(19) United States
(12) Patent Application Publication
(10) Pub. No.: US 2024/0314233 A1
(43) Pub. Date: Sep. 19, 2024

(54) Electronic Devices with Multiple Energy Storage Devices, Thermal Mitigation Circuits, and Corresponding Methods

(71) Applicant: Motorola Mobility LLC, Chicago, IL (US)

(72) Inventors: Amit Kumar Agrawal, Bangalore (IN); Xiaofeng Zhu, Nanjing (CN); Rohit Sisodia, Naperville, IL (US)

(21) Appl. No.: 18/132,210

(22) Filed: Apr. 7, 2023

Related U.S. Application Data
(63) Continuation of application No. PCT/CN2023/081728, filed on Mar. 15, 2023.

(51) Int. Cl. H04M 1/02; H05K 7/20

(52) U.S. Cl. CPC H04M 1/0268; H04M 1/0262; H05K 7/20954

(57) ABSTRACT

A deformable electronic device includes a flexible display supported by a deformable housing comprising a plurality of energy storage devices, one or more processors operable with the flexible display, and one or more sensors operable with the one or more processors. A thermal mitigation circuit operable with each energy storage device selects a subset of the plurality of energy storage devices to power the one or more processors as a function of a support condition of the deformable electronic device.

### CROSS REFERENCE TO PRIOR APPLICATIONS

This application is a continuation claiming priority and benefit under 35 U.S.C. §120, pursuant to 35 U.S.C. §365(a), to PCT Application Ser. No. PCT/CN2023/081728, filed Mar. 15, 2023, which is incorporated by reference for all purposes. See MPEP §1895.

### BACKGROUND

### Technical Field

This disclosure relates generally to electronic devices, and more particularly to electronic devices having multiple energy storage devices.

### Background Art

Portable electronic devices such as smartphones, laptop computers, tablet computers, and two-way radios derive their portability from energy storage devices, one example of which is a rechargeable electrochemical cell. In some situations, an electronic device will include two or more rechargeable cells that are coupled together in serial or in parallel. When the energy stored within the rechargeable cells becomes depleted, it is necessary to attach a power supply to the electronic device to recharge the cells.

Electronic devices using such rechargeable cells come in different mechanical configurations. A first configuration, known as a “candy bar,” is generally rectangular in shape, has a rigid form factor, and has a display disposed along a major face of the electronic device. By contrast, a “clamshell” device has a mechanical hinge that allows one housing to pivot relative to the other. Clamshell devices generally have inferior thermal dissipation performance compared to candy bar devices due to their unique design resulting in reduced thermal dissipation surface area. Moreover, new “folding” designs are being introduced that complicate this thermal dissipation issue even further. It would be advantageous to have an improved foldable design that mitigates such issues.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present disclosure.

FIG. 1 illustrates one explanatory electronic device in accordance with one or more embodiments of the disclosure.

FIG. 2 illustrates one explanatory electronic device configured in accordance with one or more embodiments of the disclosure when in a deformed “stand” configuration.

FIG. 3 illustrates a sectional view of one or more folding components and corresponding energy storage devices situated within those folding components of an electronic device configured in accordance with one or more embodiments of the disclosure.

FIG. 4 illustrates an alternate deformable housing and corresponding energy storage devices for an electronic device in accordance with one or more embodiments of the disclosure.

FIG. 5 illustrates a folding portion of a folding electronic device in accordance with one or more embodiments of the disclosure.

FIG. 6 illustrates another explanatory electronic device configured in accordance with one or more embodiments of the disclosure.

FIG. 7 illustrates one or more circuit components for an electronic device configured in accordance with one or more embodiments of the disclosure.

FIG. 8 illustrates one explanatory method in accordance with one or more embodiments of the disclosure.

FIG. 9 illustrates another explanatory method in accordance with one or more embodiments of the disclosure.

FIG. 10 illustrates one or more method steps in accordance with one or more embodiments of the disclosure.

FIG. 11 illustrates one or more method steps in accordance with one or more embodiments of the disclosure.

FIG. 12 illustrates one or more method steps in accordance with one or more embodiments of the disclosure.

FIG. 13 illustrates one or more method steps in accordance with one or more embodiments of the disclosure.

FIG. 14 illustrates one or more embodiments of the disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

### DETAILED DESCRIPTION OF THE DRAWINGS

Before describing in detail embodiments that are in accordance with the present disclosure, it should be observed that the embodiments reside primarily in combinations of method steps and apparatus components related to, in an electronic device that includes a flexible display supported by a device housing comprising a plurality of energy storage devices, where a thermal mitigation circuit selects a subset of the plurality of energy storage devices to power one or more processors of the electronic device as a function of a support condition of the deformable electronic device. Any process descriptions or blocks in flow charts should be understood as representing modules, segments, or portions of code that include one or more executable instructions for implementing specific logical functions or steps in the process. Alternate implementations are included, and it will be clear that functions may be executed out of order from that shown or discussed, including substantially concurrently or in reverse order, depending on the functionality involved. Accordingly, the apparatus components and method steps have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

Embodiments of the disclosure do not recite the implementation of any commonplace business method aimed at processing business information, nor do they apply a known business process to the particular technological environment of the Internet. Moreover, embodiments of the disclosure do not create or alter contractual relations using generic computer functions and conventional network operations. Quite to the contrary, embodiments of the disclosure employ methods that, when applied to electronic device and/or charging technology, improve the functioning of the electronic device itself by and improving the performance that can be achieved from a multiple energy storage device system in which non-zero impedances occur in circuit components coupling one energy storage device to another.

It will be appreciated that embodiments of the disclosure described herein may be comprised of one or more conventional processors and unique stored program instructions that control the one or more processors to implement, in conjunction with certain non-processor circuits, some, most, or all of the functions of determining a subset of the plurality of energy storage devices of a deformable electronic device from which to draw current to power one or more processors of the deformable electronic device as a function of a support condition of the deformable electronic device. The non-processor circuits may include, but are not limited to, a control circuit, switches, overprotection circuits, fuel gauging circuits, diodes, signal drivers, clock circuits, power source circuits, and user input devices.

As such, these functions may be interpreted as steps of a method to perform selecting which energy storage devices of a plurality of energy storage devices will power the one or more processors as a function of the support condition detected by one or more sensors of the deformable electronic device, optionally in combination with a geometric configuration of the deformable electronic device, as described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ASICs with minimal experimentation.

Embodiments of the disclosure are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions.

As used herein, components may be “operatively coupled” when information can be sent between such components, even though there may be one or more intermediate or intervening components between, or along the connection path. The terms “substantially,” “essentially,” “approximately,” “about” or any other version thereof, are defined as being close to as understood by one of ordinary skill in the art, and in one non-limiting embodiment the term is defined to be within ten percent, in another embodiment within five percent, in another embodiment within one percent and in another embodiment within one-half percent. The term “coupled” as used herein is defined as connected, although not necessarily directly and not necessarily mechanically. Also, reference designators shown herein in parenthesis indicate components shown in a figure other than the one in discussion. For example, talking about a device (10) while discussing figure A would refer to an element, 10, shown in figure other than figure A.

Embodiments of the disclosure provide circuits and methods for determining which subset of a plurality of energy storage devices in a deformable electronic device should be used to power one or more processors of the deformable electronic device as a function of a support condition of the deformable electronic device detected by one or more sensors of the deformable electronic device. In one or more embodiments, the deformable electronic device comprises a flexible display supported by a deformable housing comprising a plurality of energy storage devices. In one or more embodiments, the deformable electronic device has one or more processors operable with the flexible display and one or more sensors operable with the one or more processors.

In one or more embodiments, a thermal mitigation circuit is operable with the plurality of energy storage devices. In one or more embodiments, the thermal mitigation circuit selects a subset of the plurality of energy storage devices to power the one or more processors as a function of a support condition of the electronic device. Illustrating by example, if the support condition comprises the deformable electronic device being held at a first end of the deformable housing, the subset of plurality of energy storage devices are situated closer to a second end, situated distally across the deformable housing from the first end, than the first end of the deformable housing. By contrast, when the support condition comprises the deformable housing being held at the second end, the subset of the plurality of energy storage devices is situated closer to the first end of the deformable housing than the second end of the deformable housing. Likewise, when the support condition comprises the deformable electronic device being held at a central location of the deformable housing, the subset of the plurality of energy storage devices can include a first set of energy storage devices situated at one end of the deformable housing and a second set of energy storage devices situated at the other end of the deformable housing, with that first set of energy storage devices and the second set of energy storage devices separated by the central location.

Advantageously, these embodiments of the disclosure keep the portion of the deformable housing being held cool by precluding use of the energy storage devices at locations being held and instead using energy storage devices situated at other locations. Accordingly, when current is drawn from those energy storage devices and they warm, the user will not feel the heat since they are situated at locations of the deformable housing other than those being held.

By selecting from which subset energy storage devices to draw current, the thermal mitigation circuit can affect the overall temperature of the electronic device. For instance, when the thermal mitigation circuit draws more current from a subset situated in a first end of the deformable housing, this generally will cause the first end to be hotter than the second end where energy is not being drawn from the corresponding set of energy storage devices situated there. By making this choice when the electronic device is held by, or held predominantly by, a particular end, or central location, of the deformable housing, this allows the portion of the deformable housing being held to stay cooler than other portions that are not being held, thereby keeping the device housing portion being held by the user at a lower temperature for more comfort.

Some use cases help to illustrate this advantage. In one or more embodiments, when the support condition comprises the deformable electronic device being supported by a surface, the thermal mitigation circuit selects all energy storage devices of the plurality of energy storage devices to power the one or more processors. The thermal mitigation circuit makes this choice because warming a user's hands at a holding location is not an issue. The surface does not care whether it warms.

Similarly, when the support condition comprises a user holding, or substantially holding, the entire electronic device the thermal mitigation circuit can also select all energy storage devices to power the one or more processors. The thermal mitigation circuit can make this choice because this evenly distributes heat across the deformable housing.

When the support condition comprises the deformable electronic device being held at a first end of the deformable housing while the deformable electronic device is adjacent to an ear, the thermal mitigation circuit may select a subset of energy storage devices situated closer to the first end of the device housing than a second end of the device housing despite the fact that the user is holding the first end of the deformable housing. Embodiments of the disclosure contemplate that the ear may be more sensitive to heat than the hand. Accordingly, when the second end of the deformable housing is adjacent to an ear, as determined by the one or more sensors, in one or more embodiments the thermal mitigation circuit causes current to be drawn from a subset of the plurality of energy storage devices situated at the first end, which is being held by the user. Despite this not being preferred, it allows the heat to be absorbed by the hand rather than the ear, thereby increasing the comfort experienced by the user over electronic devices that warm the second end of the device housing includes energy storage devices drawing current as well.

Geometric configuration can be used in addition to support condition when selecting which subset of the plurality of energy storage devices will be used to power the one or more processors as well. Illustrating by example, when the geometric configuration comprises the deformable electronic device defining a loop, such as may be the case when the deformable electronic device is being worn around a wrist, the thermal mitigation circuit may select all energy storage devices of the plurality of energy storage devices to power the one or more processors. This choice is made because it evenly distributes the heat around the wrist. Other geometric configuration examples will be described below. Still others will be obvious to those of ordinary skill in the art having the benefit of this disclosure.

When the deformable electronic device is connected to a charger, the thermal mitigation circuit may work in reverse, causing more charging current to be delivered to the energy storage devices situated in portions of the deformable device housing that are not being held. This works equally well because an energy storage device heats both when it is delivering a load current and when it is receiving a charging current. Accordingly, in another use case when the deformable electronic device is connected to a charger and is being by supported by a surface, the thermal mitigation circuit may cause the energy storage devices having the lowest state of charge to receive the most charging current first. Once all energy storage devices reach the same state of charge, the thermal mitigation circuit may cause current to be delivered to all energy storage devices of the plurality of energy storage devices equally.

Things can change, however, when the electronic device is being held while connected to a charger. Illustrating by example, in another use case when the electronic device is connected to a charger and is being supported by a hand, the one or more sensors may determine whether the electronic device is being held by, or held predominantly by, at a first end of the deformable housing, a second end of the deformable housing, in a central portion of the deformable housing, or across substantially all of the deformable housing. The thermal mitigation circuit can then deliver charging current to the energy storage devices situated in portions of the deformable device housing that are not being held or predominantly held. As used herein, “predominantly.” takes the plain, ordinary, English definition of “mainly, for the most part.” Thus, if a person is holding the electronic device with a single hand where seventy percent, seventy-five percent, eighty percent, eighty-five percent, ninety percent, or ninety-five percent of the single hand contacts the first device housing, the person would be “predominantly” holding the electronic device by the first device housing.

When no charger is connected, the thermal mitigation circuit can also perform balancing operations. Illustrating by example, when the deformable electronic device is not connected to a charger and is not being used, i.e., when the deformable electronic device is idle, the thermal mitigation circuit can charge some of the energy storage devices situated in portions of the deformable housing by delivering current from other energy storage devices situated in other portions of the deformable housing. In so doing, the thermal mitigation circuit prepares the energy storage devices to be ready regardless of where a user elects to support the deformable housing.

In effect, embodiments of the disclosure optimize the current drawn from each of the energy storage devices in a multi-energy storage device/deformable device housing electronic device as a function of support condition (surface supported or hand supported), device orientation (landscape or portrait), geometric configuration (flat, loop, bent, other), and hand support location on specific portions of the deformable device housing (first end, second end, central portion, entirety). For instance, embodiments of the disclosure determine whether to draw more current from a subset of the plurality of energy storage devices situated in a second end of a deformable housing when a user is holding a first end, or vice versa. This allows the portion of the deformable device housing not being held by the user to get hotter, while the portion of the deformable device housing being held by the user stays cooler.

In one or more embodiments, a deformable electronic device comprises a flexible display spanning a first major surface of the deformable electronic device. The deformable electronic device comprises one or more processors, one or more sensors, and a thermal mitigation circuit. In one or more embodiments, the thermal mitigation circuit selects which energy storage devices of the plurality of energy storage devices will power the one or more processors as a function of a support condition detected by the one or more sensors and a geometric configuration of the electronic device.

When the support condition comprises the deformable electronic device being supported by a surface, the thermal mitigation circuit may select all energy storage devices of the plurality of energy storage devices to power the one or more processors. When the support condition comprises the deformable electronic device being held at an end of the deformable electronic device, the thermal mitigation circuit can select a subset of the plurality of energy storage devices situated at another end of the deformable electronic device to power the one or more processors. When the support condition comprises a wrist-worn support condition, the thermal mitigation circuit can also select all energy storage device of the plurality of energy storage devices to power the one or more processors to evenly distribute thermal energy around a user's wrist.

When the geometric configuration comprises the deformable electronic device being flat or substantially flat, the thermal mitigation circuit can select all energy storage devices of the plurality of energy storage devices to power the one or more processors. When the geometric configuration comprises the deformable electronic device being bent to define a loop, the one or more processors may select a subset of the plurality of energy storage devices to power the one or more processors because the deformable electronic device may not be in a wrist-worn configuration. Instead, the one or more sensors may determine that the inner loop is being supported by a finger or two, in which case the subset of the plurality of energy storage devices will be situated at locations other than where the finger or two is supporting the loop, and so forth.

Embodiments of the disclosure advantageously help to keep the portion of the deformable electronic device being held by a user nice and cool. Other advantages will be described below. Still others will be obvious to those of ordinary skill in the art having the benefit of this disclosure.

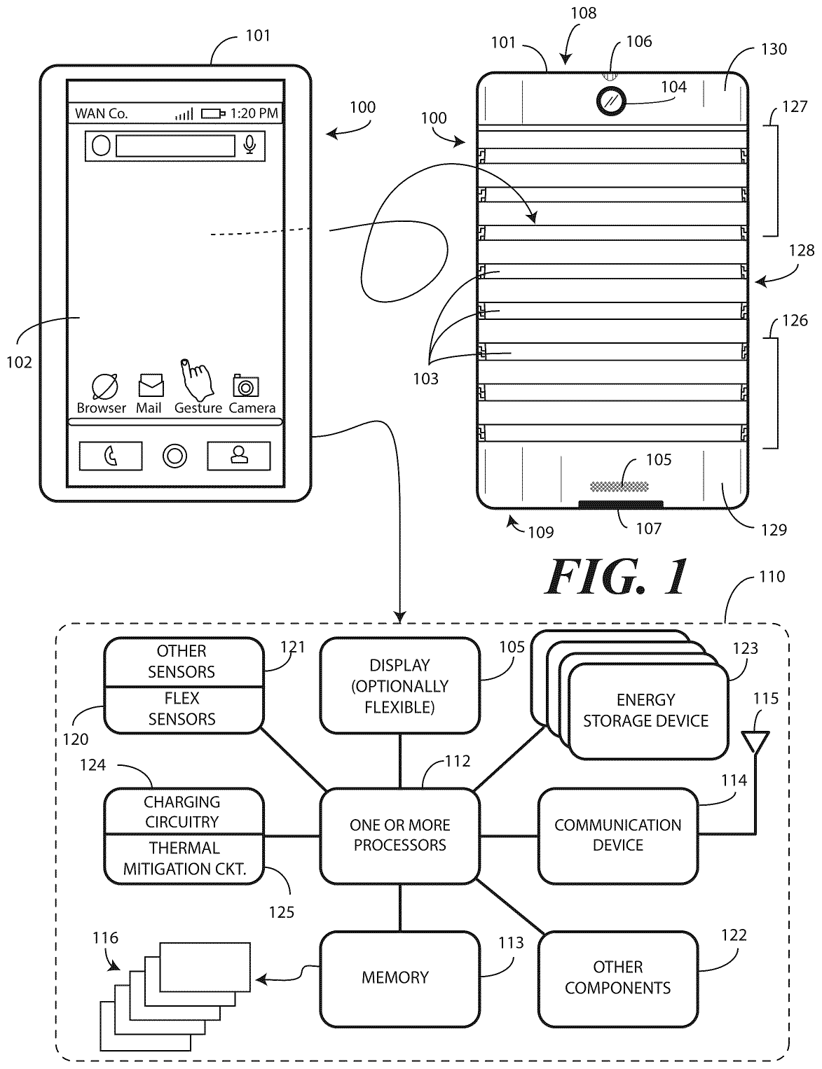

Turning now to FIG. 1, illustrated therein is one explanatory electronic device 100 configured in accordance with one or more embodiments of the disclosure. The electronic device 100 of FIG. 1 is a portable electronic device. In one or more embodiments, the electronic device 100 includes a deformable housing 101 that includes one or more linkage members 103 that allows the electronic device 100 to be deformed by bending or folding. Advantageously, this allows the electronic device 100 to function as the equivalent to multiple devices depending upon the amount of deformation of the deformable housing 101.

For example, the electronic device 100 is shown in an unbent configuration in FIG. 1, and accordingly can function as a smartphone, palm-top computer, or tablet computer. However, as will be shown below with reference to FIG. 3, in one embodiment the electronic device 100 can be folded and can accordingly function as a table clock, content viewer, or auxiliary display when in a bent condition. It should be obvious to those of ordinary skill in the art having the benefit of this disclosure that the electronic device 100 can function as other devices as a function of its physical geometry, including as a gaming device, a media player, or other device.

This illustrative electronic device 100 includes a display 102, which may optionally be touch-sensitive. In one embodiment where the display 102 is touch-sensitive, the display 102 can serve as a primary user interface of the electronic device 100. Users can deliver user input to the display 102 of such an embodiment by delivering touch input from a finger, stylus, or other objects disposed proximately with the display.

In one embodiment, the display 102 is configured as an organic light emitting diode (OLED) display fabricated on a flexible plastic substrate. However, it should be noted that other types of displays would be obvious to those of ordinary skill in the art having the benefit of this disclosure. In one or more embodiments, an OLED is constructed on flexible plastic substrates can allow the display 102 to become flexible in one or more embodiments with various bending radii. For example, some embodiments allow bending radii of between thirty and six hundred millimeters to provide a bendable display. Other substrates allow bending radii of around five millimeters to provide a display that is foldable through active bending. Other displays can be configured to accommodate both bends and folds. In one or more embodiments the display 102 may be formed from multiple layers of flexible material such as flexible sheets of polymer or other materials.

The explanatory electronic device 100 of FIG. 1 also includes a deformable housing 101 that includes one or more linkage members 103. The linkage members 103 allow portions of the deformable housing 101 to pivot about each linkage member 103 so that the electronic device 100 becomes bendable and/or foldable. While the deformable housing 101 can be manufactured from segments of a rigid material that each bend around a corresponding hinge mechanism, such as a rigid thermoplastic or composite material, other materials can be used. Illustrating by example, the deformable housing 101 can be manufactured from a bendable material that both supports the display 102 and allows for deformation of the deformable housing 101 around the linkage members 103 as well.

In this illustrative embodiment, the display 102 is coupled to the deformable housing 101. In one embodiment, the lower surface of the display 102, or another layer in the mechanical stack-up of the display 102, can be adhered to the deformable housing 101, or alternatively to portions of the deformable housing 101. In either embodiment, the display 102 also spans the linkage members 103. In one or more embodiments, the display 102 is flexible so as to deform when the deformable housing 101 bends around the linkage members 103.

Features can be incorporated into the deformable housing 101. Examples of such features include an optional image capture device 104 or an optional speaker port 105, which are shown disposed on the rear side of the electronic device 100 in this embodiment but could be placed on the front side as well. A user interface component, which may be a button or touch sensitive surface, can also be disposed along the rear side of the deformable housing 101. As noted, any of these features are shown being disposed on the rear side of the electronic device 100 in this embodiment, but could be located elsewhere, such as on the front side in other embodiments.

In one embodiment, the electronic device 100 includes one or more connectors 106,107, which can include an analog connector, a digital connector, or combinations thereof. In this illustrative embodiment, connector 106 is an analog connector disposed on a first end 108, i.e., the top end, of the electronic device 100, while connector 107 is a digital connector disposed on a second end 109 opposite the first end 108, which is the bottom end in this embodiment.

A block diagram schematic 110 of the electronic device 100 is also shown in FIG. 1. The block diagram schematic 110 can be configured as a printed circuit board assembly disposed within the deformable housing 101. Various components can be electrically coupled together by conductors or a bus disposed along one or more printed circuit boards. A flexible substrate can then span the linkage members 103 to electrically couple electronic circuits together.

In one or more embodiments, the electronic device 100 includes one or more processors 112. In one embodiment, the one or more processors 112 can include an application processor and, optionally, one or more auxiliary processors. One or both of the application processor or the auxiliary processor(s) can include one or more processors. One or both of the application processor or the auxiliary processor(s) can be a microprocessor, a group of processing components, one or more ASICs, programmable logic, or other type of processing device.

The application processor and the auxiliary processor(s) can be operable with the various components of the electronic device 100. Each of the application processor and the auxiliary processor(s) can be configured to process and execute executable software code to perform the various functions of the electronic device 100. A storage device, such as memory 113, can optionally store the executable software code used by the one or more processors 112 during operation.

In this illustrative embodiment, the electronic device 100 also includes a communication circuit 114 that can be configured for wired or wireless communication with one or more other devices or networks. The networks can include a wide area network, a local area network, and/or personal area network. The communication circuit 114 may also utilize wireless technology for communication, such as, but are not limited to, peer-to-peer or ad hoc communications such as HomeRF, Bluetooth and IEEE 802.11, and other forms of wireless communication such as infrared technology. The communication circuit 114 can include wireless communication circuitry, one of a receiver, a transmitter, or transceiver, and one or more antennas 115.

In one embodiment, the one or more processors 112 can be responsible for performing the primary functions of the electronic device 100. For example, in one embodiment the one or more processors 112 comprise one or more circuits operable with one or more user interface devices, which can include the display 102, to present, images, video, or other presentation information to a user. The executable software code used by the one or more processors 112 can be configured as one or more modules 116 that are operable with the one or more processors 112. Such modules 116 can store instructions, control algorithms, logic steps, and so forth.

In one embodiment, the one or more processors 112 are responsible for running the operating system environment of the electronic device 100. The operating system environment can include a kernel and one or more drivers, and an application service layer, and an application layer. The operating system environment can be configured as executable code operating on one or more processors or control circuits of the electronic device 100. The application layer can be responsible for executing application service modules. The application service modules may support one or more applications or “apps.” The applications of the application layer can be configured as clients of the application service layer to communicate with services through application program interfaces (APIs), messages, events, or other inter-process communication interfaces. Where auxiliary processors are used, they can be used to execute input/output functions, actuate user feedback devices, and so forth.

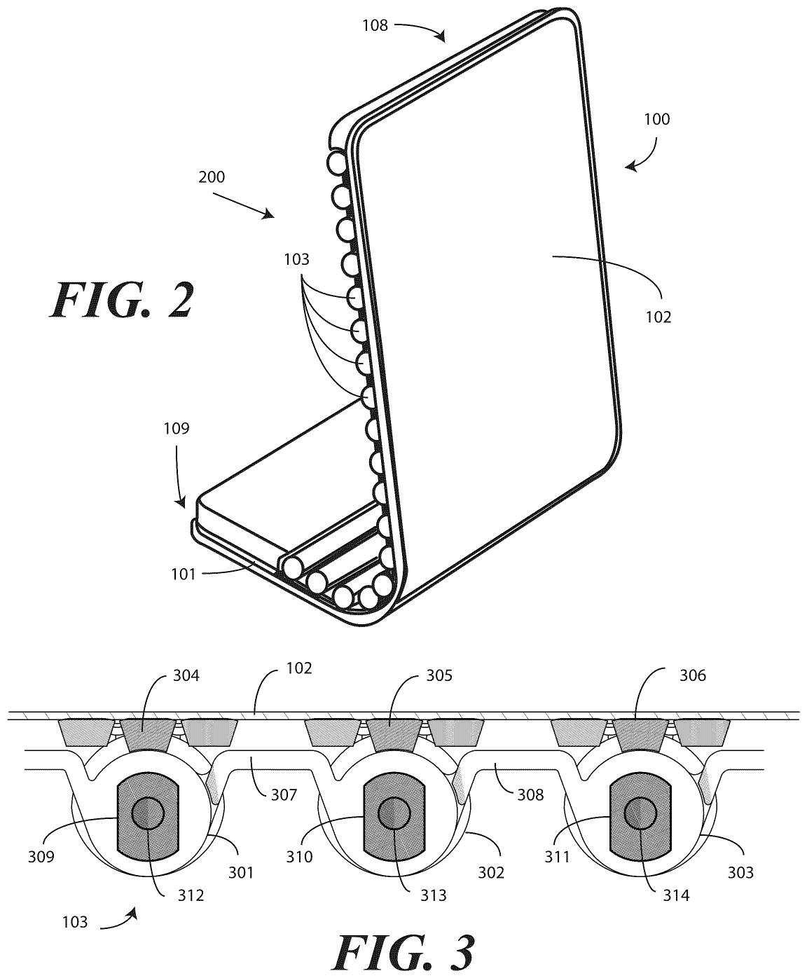

In one embodiment, the electronic device 100 optionally includes one or more flex sensors 120, operable with the one or more processors 112, to detect a bending operation that causes the deformable device housing 101 to deform, thereby transforming the electronic device 100 into a deformed geometry, such as that shown in FIG. 2. The inclusion of flex sensors 120 is optional, and in some embodiment flex sensors 120 will not be included. Where flex sensors 120 are not included and device operation is a function of the amount of deformation of the deformable housing 101, the user can alert the one or more processors 112 to the fact that the one or more bends are present through the user interface or by other techniques.

In one embodiment, the flex sensors 120 comprise passive resistive devices manufactured from a material with an impedance that changes when the material is bent, deformed, or flexed. By detecting changes in the impedance as a function of resistance, the one or more processors 112 can use the one or more flex sensors 120 to detect bending of the deformable housing 101. In one or more embodiments, each flex sensor 120 comprises a bi-directional flex sensor that can detect flexing or bending in two directions. In one embodiment, the one or more flex sensors 120 have an impedance that increases in an amount that is proportional with the amount it is deformed or bent.

In one embodiment, each flex sensor 120 is manufactured from a series of layers combined together in a stacked structure. In one embodiment, at least one layer is conductive, and is manufactured from a metal foil such as copper. A resistive material provides another layer. These layers can be adhesively coupled together in one or more embodiments. The resistive material can be manufactured from a variety of partially conductive materials, including paper-based materials, plastic-based materials, metallic materials, and textile-based materials. In one embodiment, a thermoplastic such as polyethylene can be impregnated with carbon or metal so as to be partially conductive, while at the same time being flexible.

In one embodiment, the resistive layer is sandwiched between two conductive layers. Electrical current flows into one conductive layer, through the resistive layer, and out of the other conductive layer. As the flex sensor 120 bends, the impedance of the resistive layer changes, thereby altering the flow of current for a given voltage. The one or more processors 112 can detect this change to determine an amount of bending. Taps can be added along each flex sensor 120 to determine other information, including the amount of bending, the direction of bending, and so forth. The flex sensor 120 can further be driven by time-varying signals to increase the amount of information obtained from the flex sensor 120 as well. While a multi-layered device as a flex sensor 120 is one configuration suitable for detecting at least a bending operation occurring to deform the electronic device 100 and a geometry of the electronic device 100 after the bending operation, others can be used as well. Other types of flex sensors 120 will be obvious to those of ordinary skill in the art having the benefit of this disclosure.

In one embodiment, the one or more processors 112 may generate commands or execute control operations based on information received from the various sensors, including the one or more flex sensors 120, the user interface, or the other sensors 121. The one or more processors 112 may also generate commands or execute control operations based upon information received from a combination of the one or more flex sensors 120, the user interface, or the other sensors 121. Alternatively, the one or more processors 112 can generate commands or execute control operations based upon information received from the one or more flex sensors 120 or the user interface alone. Moreover, the one or more processors 112 may process the received information alone or in combination with other data, such as the information stored in the memory 113.

The one or more other sensors 121 may include a microphone, an earpiece speaker, a second loudspeaker (disposed beneath speaker port 105), and a user interface component such as a button or touch-sensitive surface. The one or more other sensors 121 may include one or more of an accelerometer, gyroscope, image capture device, and/or display touch sensors to determine whether the electronic device 100 is being held on the base side or flip side in a portrait mode.

The one or more other sensors 121 may also include key selection sensors, proximity sensors, a touch pad sensor, a touch screen sensor, a capacitive touch sensor, and one or more switches. Touch sensors may be used to indicate whether any of the user actuation targets present on the display 102 are being actuated. Alternatively, touch sensors disposed in the electronic device 100 can be used to determine whether the electronic device 100 is being touched at side edges or major faces of the deformable housing 101. The touch sensors can include surface and/or housing capacitive sensors in one embodiment. The other sensors 121 can also include audio sensors and video sensors (such as a camera).

The other sensors 121 can also include motion detectors, such as one or more accelerometers or gyroscopes. For example, an accelerometer may be embedded in the electronic circuitry of the electronic device 100 to show vertical orientation, constant tilt and/or whether the electronic device 100 is stationary. A gyroscope can be used in a similar fashion.

Other components 122 operable with the one or more processors 112 can include output components such as video outputs, audio outputs, and/or mechanical outputs. Examples of output components include audio outputs such as speaker port 105, earpiece speaker, or other alarms and/or buzzers and/or a mechanical output component such as vibrating or motion-based mechanisms. Still other components will be obvious to those of ordinary skill in the art having the benefit of this disclosure.

In one or more embodiments, the electronic device 100 comprises a plurality of energy storage devices 123. In one or more embodiments, as will be explained in more detail below with reference to FIG. 2, the plurality of energy storage devices 123 include an energy storage device situated in each linkage member 103. In one or more embodiments, each energy storage device of the plurality of energy storage devices 123 situates in a corresponding linkage member 103 on a one-to-one basis. Each energy storage device of the plurality of energy storage devices 123 can take a variety of forms.

In the illustrative embodiment of FIG. 1, the plurality of energy storage devices 123 are situated on a rear side of the deformable device housing 101. In this example, the plurality of energy storage devices 123 are situated between an electronics component enclosure 129 and an end cap 130. In one or more embodiments, each energy storage device of the plurality of energy storage devices 123 spans a width of the deformable electronic device as shown in FIG. 1.

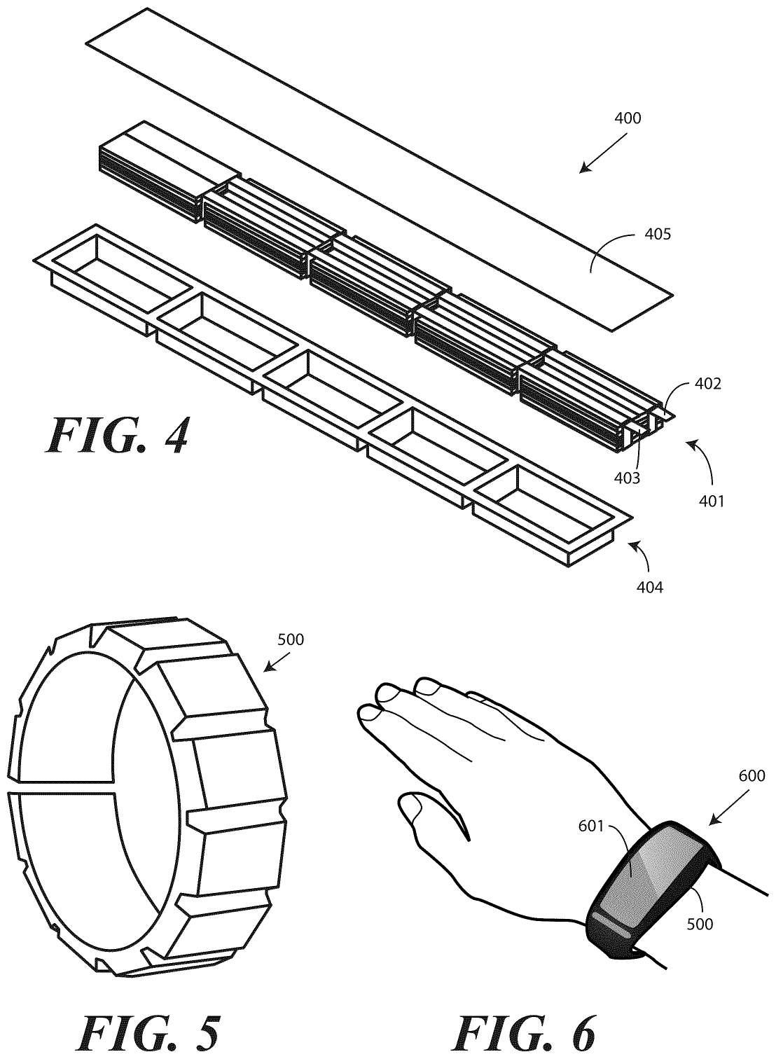

In an illustrative embodiment shown below in FIGS. 2 and 4, each energy storage device of the plurality of energy storage devices 123 can comprise an electrochemical cell. For instance, the plurality of energy storage devices 123 can each comprise a lithium-ion, lithium-polymer, or other type of rechargeable cell. Other examples of energy storage devices suitable for use with embodiments of the disclosure will be obvious to those of ordinary skill in the art having the benefit of this disclosure. For instance, in other embodiments the plurality of energy storage devices 123 may be a supercapacitor, and so forth.

In one or more embodiments, a first energy storage device is situated in a first hinge mechanism, with a second energy storage device situated in a second hinge mechanism, and so forth. In one or more embodiments, an electrical conductor couples the energy storage devices of the plurality of energy storage devices 123 together and/or to the one or more processors 112.

Charging circuitry 124 can be included to selectively individual, subsets, or all of the plurality of energy storage devices 123 when depleted. In one or more embodiments, the charging circuitry 124 comprises a charging node that is coupled to each energy storage device of the plurality of energy storage devices 123.

In one or more embodiments, the charging circuitry 124 includes a switch that is electrically coupled between the conductor coupling the plurality of energy storage devices 123. Opening the switch disconnects the conductor from the plurality of energy storage devices 123, while closing the switch couples the plurality of energy storage devices 123 to the components of the block diagram schematic 110.

In one or more embodiments, a thermal mitigation circuit 125 is operable to power the one or more processors 112 and other components of the block diagram schematic 110 from one, some, or all energy storage devices of the plurality of energy storage devices 123. Illustrating by example, in one or more embodiments the thermal mitigation circuit 125 powers the one or more processors 112 with current from a subset of the plurality of energy storage devices 123 as a function of a support condition of the electronic device 100.

For instance, when the support condition comprises the electronic device 100 being held at a first end 108 of the deformable housing 101, the thermal mitigation circuit 125 may select a subset 126 of the plurality of energy storage devices 123 situated closer to the second end 109 of the deformable housing 101 to power the one or more processors 112, thereby keeping the first end 108 of the deformable housing 101 cooler than the second end 109. By contrast, when the support condition comprises the electronic device 100 being held at the second end 109 of the deformable housing 101, the thermal mitigation circuit 125 may select another subset 127 of the plurality of energy storage devices 123 situated closer to the first end 108 of the deformable housing 101 to power the one or more processors 112 for the same reason.

When the support condition comprises the electronic device 100 being held at a central portion 128 of the deformable housing 101, the thermal mitigation circuit 125 may select a first subset 126 of the plurality of energy storage devices 123 and a second subset 127 of the plurality of energy storage devices 123 that are separated from the first subset 126 of the plurality of energy storage devices 123 by the central portion 128 to power the one or more processors 112. However, when the support condition comprises the electronic device 100 being supported by a surface, where warming a user's hand is not at issue, the thermal mitigation circuit 125 may select all energy storage devices of the plurality of energy storage devices 123 to power the one or more processors 112. In the same manner, when the support condition comprises all, or substantially all, of the deformable housing 101 being held, which means that all, or substantially all, of the energy storage devices of the plurality of energy storage devices 123 are being held, the thermal mitigation circuit 125 may also select all energy storage devices of the plurality of energy storage devices 123 to power the one or more processors 112, thereby evenly distributing heat dissipation across the entirety of the deformable housing 101.

This preferred mode of operation where energy storage devices of the plurality of energy storage devices 123 situated “away from” the portion of the deformable housing 101 can be interrupted under certain conditions, however. For example, when the support condition comprises the deformable housing 101 being held at a second end 109 while the first end 108 of the deformable housing 101 is adjacent to an ear, the thermal mitigation circuit 125 may select a subset 126 of the plurality of energy storage devices 123 situated closer to the second end 109 of the electronic device 100 despite the fact that the user is holding the second end 109. Embodiments of the disclosure contemplate that an ear may be more sensitive to heat than a hand. Accordingly, between the choice of heating the hand or heating the ear, in some embodiments the thermal mitigation circuit 125 will make a selection to heat the ear. In other embodiments, the thermal mitigation circuit 125 will simply select energy storage devices of the plurality of energy storage devices 123 situated at the central portion 128 to keep both ear and hand cool.

The thermal mitigation circuit 125 can also select the subset of the plurality of energy storage devices 123 to power the one or more processors 112 as a function of the geometric configuration of the electronic device 100. Examples of this will be described below with reference to FIG. 12, where the electronic device 100 is configured as a loop being worn on a wrist. Where this wrist-worn, loop deformed condition exists, the thermal mitigation circuit 125 may select all energy storage devices of the plurality of energy storage devices 123 to power the one or more processors 112, thereby evenly distributing any thermal dissipation across the entire wrist.

When a charger is coupled to the electronic device 100, the operation can work the same way with respect to charging current being delivered to the plurality of energy storage devices 123. As with discharge, the thermal mitigation circuit 125 can select a subset of the plurality of energy storage devices 123 to be charged as a function of the support condition as well. If, for example, a user is holding the first end 108 of the deformable housing 101, the thermal mitigation circuit 125 can charge a subset 126 of the plurality of energy storage devices 123 situated closer to a second end 109, and vice versa. Since both charging and discharging works to warm energy storage devices, this “charge where the electronic device 100 is not being held” techniques helps keep those portions of the deformable housing 101 not being held comfortable and cool.

In effect, the one or more processors 112 are powered from current from energy storage devices situated in the deformable housing 101 at portions of the deformable housing 101 other than the portions being held. Thus, if a user is holding the first end 108 of the deformable housing 101 and the subset 126 of the plurality of energy storage devices 123 situated closer to the second end 109 of the deformable housing 101 are sufficiently charged, that subset 126 can power the one or more processors 112. Likewise, if a user is holding the second end 109 and the subset 127 situated closer to the first end 108 is sufficiently charged, the one or more processors 112 can be powered by this subset 127. This works to keep the portion of the deformable housing 101 the user is holding cool since the other portions of the deformable housing 101 will warm due to the discharge of current.

Other actions that may suspend this preferred mode of operation comprise the electronic device 100 being held by, or held predominantly by, a portion of the deformable housing 101 while the energy storage devices situated in that portion are more charged than are other energy storage devices situated distally from the portion while a performance application is operating on the one or more processors 112. (As used herein, a “performance application” is an application requiring a majority of the computing resources offered by the one or more processors 112. Examples of performance applications include gaming applications, cryptocurrency mining applications, and high-resolution video processing applications.) Embodiments of the disclosure contemplate that when such a performance application is operating on the one or more processors, it will be desirable to draw current from the most charged energy storage devices even when the user is holding a portion of the deformable housing 101 where those most charged energy storage devices are situated because those energy storage devices will allow the one or more processors 112 to perform at top speed.

In still other embodiments, an anomalous condition comprises the electronic device 100 being held by, or held predominantly by, the second end 109 while the first end 108 is adjacent to an ear. For example, when the electronic device 100 is configured as a smartphone as is the case in FIG. 1, embodiments of the disclosure contemplate that the ear may actually be more sensitive to heat than is the hand. Accordingly, when the first end 108 is adjacent to an ear, as determined by the one or more sensors 121, in one or more embodiments the thermal mitigation circuit 125 causes current from a subset 126 situated closer to the second end 109 to power the one or more processors 112 and other circuitry despite the user holding the second end 109. Despite this not being preferred, it allows the heat to be absorbed by the hand rather than the ear, thereby increasing the comfort experienced by the user over electronic devices that warm the portion adjacent to the ear as well. However, when the electronic device 100 is removed from the ear, the thermal mitigation circuit 125 may again select the subset 127 of plurality of energy storage devices 123 situated away from the portion of the deformable housing 101 being held. These operating contexts are illustrative only. Others will be described below. Still others will be obvious to those of ordinary skill in the art having the benefit of this disclosure.

It should be noted that the thermal mitigation circuit 125 can be a stand-alone, hardware component such as an integrated circuit operable with one or more switches and/or relays to perform the operations described above. The thermal mitigation circuit 125 can be operable with the one or more processors 112. Alternatively, the functions of the thermal mitigation circuit 125 can be performed by the one or more processors 112. The thermal mitigation circuit 125 can be a hardware component of the one or more processors 112, integrated into the one or more processors 112, and so forth. Thus, as described above, in one or more embodiments the one or more processors 112 can select a subset of the plurality of energy storage devices 123 from which to draw current to power the one or more processors 112 of the electronic device 100 as a function of a support condition of the electronic device 100.

It is to be understood that FIG. 1 is provided for illustrative purposes only and for illustrating components of one electronic device 100 in accordance with embodiments of the disclosure and is not intended to be a complete schematic diagram of the various components required for an electronic device. Therefore, other electronic devices in accordance with embodiments of the disclosure may include various other components not shown in FIG. 1 or may include a combination of two or more components or a division of a particular component into two or more separate components, and still be within the scope of the present disclosure.

A user can perform a bending operation upon the electronic device 100. For example, a user can apply force at the first end 108 and the second end 109 of the electronic device 100 to pivot portions of the deformable housing 101 relative to other portions of the deformable housing 101. This method of deforming the deformable housing 101 allows the user to simply and quickly bend the electronic device 100 into a desired shape.

In other embodiments, rather than relying upon the manual application of force, the electronic device 100 can include a mechanical actuator to deform the deformable housing 101 around the linkage members 103. For example, a motor or other mechanical actuator can be operable with structural components to deform the deformable housing 101 around the linkage members 103 to predetermined angles or geometric alignments in one or more embodiments. The inclusion of a mechanical actuator allows a precise bend angle to be repeatedly achieved without the user having to make adjustments. However, as the inclusion of a mechanical actuator can increase cost, in other embodiments this component will be omitted.

It should be noted that in one or more embodiments, the display 102 has a compliance coefficient that can be used advantageously to help counter the bending operation. Illustrating by example, when the bending operation transforms the electronic device 100 to a bent configuration, one example of which is shown below with reference to FIG. 3, in one or more embodiments the mechanical layers of the display 102 are loaded by the bending operation and work to bias portions of the deformable housing 101 back to the open position of FIG. 1. Moreover, in one or more embodiments a thin stainless-steel plate (approximately 0.04 millimeters in thickness) forms one layer of the display 102 and will increase the loading. This mechanical loading of the layers of the display 102 can be used to help the user transform the electronic device 100 from folded or partially folded configurations to unfolded configurations in one or more embodiments. The modulus of the display 102 can range from 40-300 giga-Pascals in one or more embodiments.

Regardless of whether the bending operation is a manual one or is instead one performed by a mechanical actuator, it results in the display 102 being deformed by one or more bends about the linkage members. Turning briefly to FIG. 2, illustrated therein is one result of the bending operation.

In the illustrative embodiment of FIG. 2, the electronic device 100 has been placed on a table or other flat surface, with the bending operation leaving the electronic device to resemble a card folded into a “tent fold” having a single bend. This bent configuration can make the display 102 easier for the user to view since they do not have to hold the electronic device 100 in their hands.

As shown in FIG. 2, the display 102 is deformed about the linkage members 103 as portions of the deformable housing 101 are bent into a “stand” configuration 200. In this illustrative embodiment, the display 102 has a single bend about the linkage members 103. However, in other embodiments, the display 102 can be deformed with a plurality of bends about the linkage members. Other configurations will be obvious to those of ordinary skill in the art having the benefit of this disclosure.

In one embodiment, the one or more processors (112) of the electronic device 100 are operable to detect that a bending operation is occurring by detecting a change in an impedance of the one or more flex sensors (120). The one or more processors (112) can detect this bending operation in other ways as well. For example, the touch sensors can detect touch and pressure from the user. Alternatively, the proximity sensors can detect the first end 108 and the second end 109 of the electronic device 100 getting closer together. Force sensors can detect an amount of force that the user is applying to the deformable housing 101 as well. The user can input information indicating that the electronic device 100 has been bent using the display 102 or another user interface. Other techniques for detecting that the bending operation has occurred will be obvious to those of ordinary skill in the art having the benefit of this disclosure.

In one or more embodiments, the one or more processors (112) can partition the display 102 of the electronic device 100 as another function of the geometric alignment of the deformable housing 101 resulting from the bending operation. For example, in this embodiment the display 102 has been partitioned into a first portion that is visible and a second portion (facing into the surface upon which the electronic device 100 rests), with each portion being disposed on opposite sides of the stand bend. In one or more embodiments, the one or more processors (112) can detect a bend amount as well.

In one or more embodiments, the one or more processors (112) of the electronic device are operable to, when the display 102 is deformed by one or more bends, present a first image on a first portion of the display 102, while presenting a second image on a second portion of the display 102. If, for example, the electronic device 100 were turned such that the first end 108 and the second end 109 were resting on the surface, the electronic device 100 would resemble a tent with a first portion of the display 102 visible from a first side of the bend and a second portion of the display 102 visible from a second side of the bend. This is a “tent” configuration.

The electronic device 100 can operate in many different configurations. A first configuration is an open configuration, such as that shown in FIG. 1, where the deformable housing 101 is flat. A second configuration is a bent configuration, such as that shown in FIG. 2, where the deformable housing 101 is deformed to define an angle. A third configuration is a folded configuration where the deformable housing 101 is bent over such that the first end 108 and the second end 109 touch.

In one or more embodiments, the operational mode of the electronic device 100 can change as a function of its geometry. Illustrating by example, the electronic device 100 might function as a palm-top computer when in the open configuration. By contrast, when in the bent configuration, the electronic device 100 may function as an alarm clock, as the electronic device 100 easily rests on a flat surface. Alternatively, as shown in FIG. 6, the electronic device 100 may be configured as a loop and worn around a wrist. When in a fully folded configuration, the electronic device 100 may function as a smartphone or other device. These functions are illustrative only, as the geometry-based predefined mode of operation could also be any number of other modes, as will be obvious to those of ordinary skill in the art having the benefit of this disclosure.

Turning now to FIG. 3, illustrated therein are sectional views of the linkage members 103 that allow deformation of the electronic device (100). As shown, the linkage members 103 define a multi-link hinging mechanism for the electronic device (100). While three linkage members 301,302,303 are shown for simplicity, in most embodiments an electronic device (100) will include more linkage members. However, in some embodiments electronic devices configured in accordance with embodiments of the disclosure can include fewer linkage as well.

In one embodiment, each of the linkage members 301,302,303 is stepped with the rigid purlins 304,305,306 to receive and protect the display 102, which is flexible. In one or more embodiments, a locking bar can be integrated with the linkage members 301,302,303 to further improve rigidity and constrain motion.

As used herein, a “purlin” is defined as a beam along a width of the flexible display, which rests between two links and supports a major face the flexible display. This is similar to the architectural purlin, which is a horizontal beam along the length of a roof, resting on a main rafter and supporting the common rafters or boards. The purlins 304,305,306 disposed between the display 102 and the linkage members 301,302,303 provide mechanical support along the major surface of the display 102.

In this illustrative embodiment, linkage members 301,302,303 are all similarly configured with links 307,308 separating each linkage member 301,302,303. Each linkage member 301,302,303 comprises a pivot 309,310,311. The pivot 309,310,311 can be configured with mechanical features that provide drive functions, resistance functions, stage stop functions, and other functions that alter the way that the electronic device (100) deforms. For example, the pivot 309,310,311 can house cam and follower assemblies, geared assemblies, spring assemblies, and other assemblies that assist the electronic device (100) in deforming, oppose the way that the electronic device (100) deforms, or otherwise increase or decrease the amount of force required to cause the electronic device (100) to deform.

In one or more embodiments, each pivot 309,310,311 comprises an energy storage device 312,313,314. In one or more embodiments, each energy storage device 312,313,314 comprises a rechargeable electrochemical cell. In some embodiments, the rechargeable electrochemical cells are surrounded by a sheath, with the sheath rotating when the linkage members 301,302,303 rotate about the pivots 309,310,311.

In one or more embodiments, the rechargeable electrochemical cells include a positive electrode (cathode), a negative electrode (anode), and a separator that prevents these two electrodes from touching. While a separator electrically separates the cathode and anode, the separator permits ions to pass through.

In one or more embodiments, a separator having a top and bottom is placed atop an electrode. Disposed on the top of the separator is a first layer of an electrochemically active material. For example, the first layer may be lithium or a lithium intercalation material if the rechargeable electrochemical cells are lithium ion or lithium polymer cells.

Disposed atop first layer is a current collecting layer. The current collecting layer may be fabricated of any of a number of metals or alloys known in the art. Examples of such metals or alloys include, for example, nickel, aluminum, copper, steel, nickel plated steel, magnesium doped aluminum, and so forth. Disposed atop the current collection layer is a second layer of electrochemically active material.

The rechargeable electrochemical cells store and deliver energy by transferring ions between electrodes through a separator. For example, during discharge, an electrochemical reaction occurs between electrodes. This electrochemical reaction results in ion transfer through the separator, which causes electrons to collect at the negative terminal of the cell. When connected to a load, such as the electronic components of the block diagram schematic (110) of FIG. 1, the electrons flow from the negative pole through the circuitry in the load to the positive terminal of the cell. This is shown in conventional circuit diagrams as current flowing from the cathode to the anode.

When the rechargeable electrochemical cells are charged, the opposite process occurs. Thus, to power electronic devices such as the electronic device (100) of FIG. 1, these electrons must be delivered from the cell to the electronic device (100). This is generally accomplished by coupling conductors, such as conductive foil strips, sometimes referred to colloquially as “electrical tabs” to the various layers.

This electrode construct can then be stacked. Once stacked, the electrode stack can be rolled into a “jellyroll” configuration so that the same can be placed in a cylindrical can that defines the exterior surface of the rechargeable electrochemical cell. Illustrating by example, two electrodes constructed as described above can be stacked, with one electrode fabricated with a layer of active electrode material, such as an electrochemically active negative electrode material, while the other electrode is fabricated with a layer of electrochemically active positive electrode material.

A first tab can be coupled to one electrode, while a second tab is coupled to the other electrode. These tabs can be coupled to the current collectors of each electrode.

In one or more embodiments, the electrodes are arranged in stacked relationship, with the tabs being disposed on opposite edges of the stack. Thereafter, the stack is rolled into a roll, sometimes referred to as a “jellyroll,” for a subsequent insertion into an electrochemical cell housing such as the cylindrical cans shown in FIG. 3. The cylindrical cans can each be a metal can or a plastic can. They can also be a flexible pouch, such as would be the case where the electrode assembly was a prismatic electrode assembly. Where metal or plastic, the housing can be configured to be cylindrical such that the rechargeable electrochemical cells can situated within each linkage member 301,302,303. However, in other constructs the rechargeable electrochemical cell can be rectangular or ovular in cross section. Where non-cylindrical such rechargeable electrochemical cells can be configured to serve as the pivot 309,310,311.

When the electrodes are rolled, one tab will end up substantially in the center of the roll, while the other tab will end up generally on the periphery of the roll. When the roll is placed in the cylindrical can housing, this results in one tab being be centrally disposed within the cylindrical can, while the other tab is disposed peripherally within the cylindrical can.

These tabs can be routed different ways within the cylindrical cans. In one or more embodiments one tab is routed to the right end of the cylindrical can, which serves as one external electrode for the rechargeable electrochemical cell. Meanwhile, the other tab is routed to the left end of the cylindrical can, which serves as the other external electrode for the rechargeable electrochemical cell. This construct, which is used in FIG. 3, works well when the rechargeable electrochemical cell is used as the pivot 309,310,311 in that one electrical contact can be biased against the first external electrode on the right end of the rechargeable electrochemical cell, while another electrical contact is biased against the second electrode on the left end of the rechargeable electrochemical cell. The rechargeable electrochemical cell can then rotate as the linkage members 301,302,303 are actuated with each electrical contact remaining stationary and biased against a single location of first external electrode on the right end of the rechargeable electrochemical cell and the second electrode on the left end of the rechargeable electrochemical cell, respectively.

In other embodiments, however, both tabs can be routed to one end of the rechargeable electrochemical cell. A first external electrode and a second external electrode can be positioned on the same end of the rechargeable electrochemical cell. The first external electrode and the second external electrode can then be concentrically aligned. This allows the rechargeable electrochemical cell to be used as the pivot 309,310,311 in the assembly. One electrical contact can be biased against the first external electrode while another electrical contact is biased against the second electrode. The rechargeable electrochemical cell can then rotate as the linkage members 301,302,303 are actuated with each electrical contact remaining stationary and biased against a single location of first external electrode and the second electrode, respectively.

In other embodiments, such as where both tabs routed to a single end of the rechargeable electrochemical cell with the first external electrode and the second external electrode arranged in a line, a sheath or other component can be positioned about the exterior of the rechargeable electrochemical cell. That component can then rotate when the linkage members 301,302,303 actuate with the rechargeable electrochemical cell remaining stationary.

For the rechargeable electrochemical cells, the cylindrical cans can be sealed in a variety of ways. In one illustrative embodiment, the cylindrical cans can be sealed by a lid defining each end of the cylindrical can. The lids, which can be manufactured from metal, are connected to the internal tabs and serve as one electrical terminal of the rechargeable electrochemical cells. An insulator can be provided to isolate the lid from the other tab. The second tab can be the coupled to another location, be it the left end, the outer, concentrically aligned external electrode, or the second external electrode. In other embodiments, such as when the cylindrical cans are manufactured from aluminum, the cylindrical can itself can be connected to the cathode. Conversely, where the cylindrical can is manufactured from steel, it will be connected to the anode.

In alternate embodiments, the tabs can be connected to a terminal block rather than to the lid and housing. The end of each energy storage device 312,313,314 could comprise a terminal block, for example. The terminal block, where employed, provides a convenient way for both the positive terminal and negative terminal to reside on a common end of the energy storage device 312,313,314. In one or more embodiments coatings, wraps, overlays, or other components can be applied the cylindrical cans when the rechargeable electrochemical cells are used as the pivots 309,310,311.

In one or more embodiments, the linkage members 301,302,303 provide one or more different mechanical functions for the electronic device (100). Illustrating by example, the linkage members 301,302,303 can provide mechanical support for the display 102 when the deformable housing (101) is planar in the open position shown above in FIG. 1. Moreover, when the electronic device (100) is in the folded position, the purlins 304,305,306 move together to provide full support for the underside major surface of the display 102, which is disposed adjacent to the linkage members 301,302,303.

In one or more embodiments, the linkage members 301,302,303 can be configured to provide one or more optional mechanical functions as well. For example, in one embodiment, the linkage members 301,302,303 provide a stop stage that operates to retain the electronic device (100) in a planar geometric configuration. If the amount of force required to deform the electronic device (100) is, for example, five Newtons ordinarily, the inclusion of a stop stage in the linkage members 301,302,303 may require a greater amount of force, such as eleven Newtons, to bend the electronic device (100) from the open position.

In one or more embodiments, the linkage members 301,302,303 are not only operable to facilitate bending of the electronic device (100) but also to electronics component enclosure (129) and the end cap (130). Embodiments of the disclosure contemplate that for optimal bending of the flexible display, it can be advantageous for the overall length of the electronic device (100) to change during bending operations. Illustrating by example, embodiments of the disclosure contemplate that maximum support for the flexible display occurs when the electronic device is shorter in the tent configuration than when in the open position or folded position. This is true because reducing the length during bending allows for the equivalent of a service loop to be defined in the display 102, thereby reducing wear. Accordingly, in one or more embodiments the linkage members 301,302,303 are configured to separate when the electronic device (100) is in the axially displaced open position.

Turning now to FIG. 4, illustrated therein is an alternate energy storage device structure for a deformable electronic device. FIG. 4 illustrates a segmented energy storage device assembly configured in accordance with one or more embodiments. As shown in FIG. 4, a plurality of stacked electrode assemblies 401 are disposed in series.

The stacked electrode assemblies 401 of this embodiment are coupled in parallel by a first common conductor 402 and a second common conductor 403. The first common conductor 402 and the second common conductor 403 can be manufactured, in one embodiment, from an electrically conductive, bendable metal such as aluminum or copper. In one embodiment, the first common conductor 402 and the second common conductor 403 are manufactured from the same material. For example, both common conductors can be manufactured from nickel. In another embodiment, the first common conductor 402 and the second common conductor 403 are manufactured from different materials. The first common conductor 402 can be copper while the second common conductor 403 is nickel for example.

In one embodiment, one or both of the first common conductor 402 and the second common conductor 403 are unitary elements. As used herein, “unitary” means a single or uniform entity comprising a single piece of material in accordance with common English parlance. By contrast, a “segmented” element would be a single element that is made from several distinct portions being joined together. Thus, in one embodiment one or both of the first common conductor 402 and the second common conductor 403 comprise a unitary conductor. In other embodiments, one or both of the first common conductor 402 and the second common conductor 403 comprise segmented conductors where multiple conductive elements are soldered, welded, or otherwise electrically coupled together to form a single element.

In one embodiment, the first common conductor 402 is coupled to each anode \of each stacked electrode assembly 401. For example, the first common conductor 402 can be coupled to each negative tab of each stacked electrode assembly 401. Similarly, in one embodiment, the second common conductor 403 is coupled to each cathode of each stacked electrode assembly 401. The second common conductor 403 can be coupled to each positive tab of each stacked electrode assembly 401 in one embodiment.

In one embodiment, one or more of the first common conductor 402 or the second common conductor 403 can include a distally extending portion that extends distally beyond an end of the segmented electrode assembly 400. The “end” is used to refer to a minor side when the segmented electrode assembly 400 is viewed in plan view.

In one embodiment, one or more of the first common conductor 402 or the second common conductor 403 is disposed interior to a side of the segmented electrode assembly 400. As used herein, the “side” refers to a major side when the segmented electrode assembly 400 is viewed in plan view. In the embodiment of FIG. 4, both the first common conductor 402 and the second common conductor 403 are disposed interior to the sides.

FIG. 4 also illustrates a receiver housing 404 and a cover housing 405 configured in accordance with one or more embodiments of the disclosure. The receiver housing 404 defines a plurality of bays in one or more embodiments. Each bay can comprise a recess or enclosed area within the receiver housing 404 in one or more embodiments. Each bay includes one or more sidewalls that extend from an open side of the receiver housing 404 and terminate at a floor.

In one embodiment, the receiver housing 404 comprises a unitary housing. For example, in one embodiment the receiver housing 404 and its bays can be manufactured from a single piece of molded thermoplastic. In one embodiment, the thermoplastic comprises a flexible plastic or plastic material to allow for its easy bending and twisting. In other embodiments, the housing 404 can be manufactured from laminated foil. Illustrating by example, a foil core layer can be coated in another material, such as plastic, to form the laminate foil.

In one embodiment, each bay is separated by a flexible connector section defined in the receiver housing 404. Where the material from which the receiver housing 404 is manufactured is flexible, each flexible connector section can be configured to bend and flex between each bay. In one embodiment, the receiver housing 404 can optionally include one or more exterior ledges having a major axis substantially orthogonal with and axis of the flexible connector sections.

In one embodiment, various portions of the receiver housing 404 can be configured to have different flex or bend coefficients. For example, in one embodiment each bay can be configured to be stiffer than each flexible connector section to allow the latter to bend of flex more readily than the former. In one embodiment, the different bend coefficients can be created by varying the thickness of portions of the receiver housing 404. Portions that are to bend less can be thicker while portions that are to bend more can be made thinner and so forth.

The cover housing 405 can be configured to couple to the receiver housing 404 to enclose and seal each bay. For example, the cover housing 405 can be manufactured from a flexible thermoplastic as is the receiver housing 404. In other embodiments, the cover housing 405 can be manufactured from laminated foil. The cover housing 405 can be thermally bonded to the receiver housing 404, adhesively bonded to the receiver housing 404, sonically welded to the receiver housing 404, or otherwise coupled to the receiver housing 404. When so coupled, the cover housing 405 and the receiver housing 404 form a sealed housing assembly.

In one or more embodiments, the segmented electrode assembly 401 is placed into the receiver housing 404 such that each stacked electrode assembly is disposed in the plurality of bays. In this embodiment, the stacked electrode assemblies seat within bays on a one-to-one basis. Each bay can then be filled with electrolyte to transform the stacked electrode assemblies into electrochemical cells.

When the stacked electrode assemblies are disposed within the bays, the first common conductor 402 and the second common conductor 403 traverse from bay to bay across the flexible connector sections. Said differently, when each electrode assembly is seated within its corresponding bay, the first common conductor 402 and the second common conductor 403 pass from one electrochemical cell in one bay to another electrochemical cell in another bay by passing over a flexible connection section. The cover housing 405 is then coupled to the receiver housing 404 such that the first common conductor 402 and/or the second common conductor 403 traverses the bays between the flexible connector sections and the cover housing 405.

In one or more embodiments one or more of the first common conductor 402 and the second common conductor 403 have a portion thereof external to the assembly forming the segmented energy storage assembly. In one embodiment, the portions extending from the assembly can be extensions of the common conductors themselves. In another embodiment, the portions can be conductors coupled to the common conductors.

The assembly can, in one or more embodiments, then be used as a deformable housing for an electronic device. Turning now to FIG. 5, the segmented energy storage assembly of FIG. 4 has been transformed into a mechanical housing 500. The mechanical housing 500 provides mechanical structure, and optionally an aesthetically pleasing appearance, for an electronic device. When the flexible connector sections of the segmented energy storage assembly flex, the mechanical housing 500 appears to be a segmented or linked bracelet on a watch or other wrist-worn device. Mechanical couplers can be coupled to the ends of the mechanical housing 500 to serve as a clasp for the segmented or linked bracelet. As shown in FIG. 6, when a flexible display 601 is attached to the mechanical housing 500, the electronic device 600 can be wrist-worn like a watch when configured as a loop.

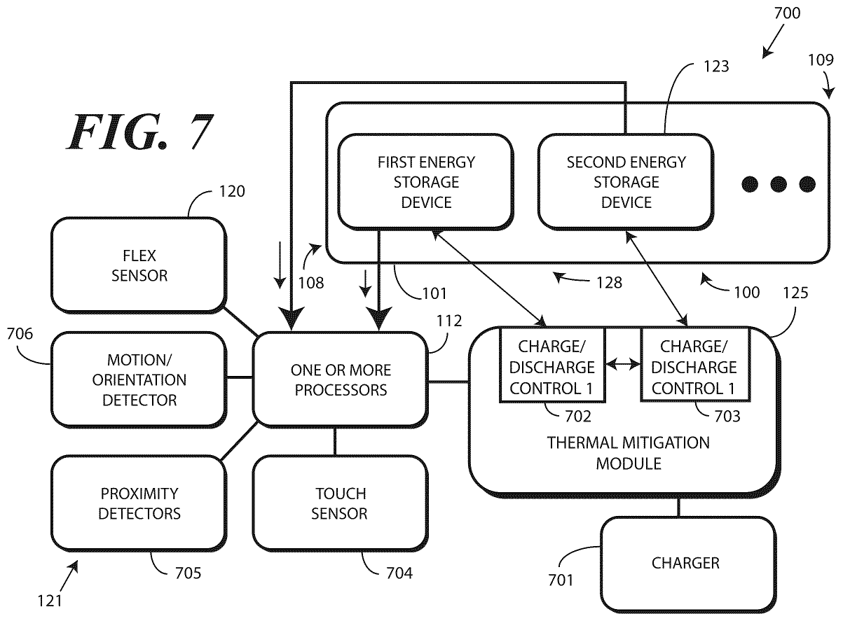

Turning now to FIG. 7, illustrated therein is a schematic diagram 700 illustrating further details of one example the electronic device 100 of FIG. 1 (or alternatively the electronic device (600) of FIG. 6). As shown, the electronic device 100 includes a deformable housing 101. A plurality of energy storage devices 123 are situated in, or along a major surface of, the deformable housing 101. While two energy storage devices are shown for brevity, the plurality of energy storage devices 123 could include many more as was the case in both FIG. 1 and FIG. 6 above.

In one or more embodiments, the thermal mitigation circuit 125 is operable with the plurality of energy storage devices 123. In one or more embodiments, the thermal mitigation circuit 125 comprises charge and discharge control 702,703 for each of energy storage device of the plurality of energy storage devices 123. The charge and discharge control 702,703 is responsible for charging, and discharging, each energy storage device of the plurality of energy storage devices 123.

When a charger 701 is coupled to the thermal mitigation circuit 125, the charge and discharge control 702,703 can charge each energy storage device of the plurality of energy storage devices 123, respectively. The charge and discharge control 702,703 can also power the one or more processors 112 and other components of the electronic device 100.

One or more sensors 121 of the electronic device 100 are shown in FIG. 7. In this illustration, the one or more sensors 121 comprise a flex sensor 120 configured to determine whether the electronic device 100 is in a planar, flat geometric configuration or in a deformed geometric configuration, examples of which include a bent geometric configuration, a tent geometric configuration, a loop geometric configuration, a multi-bend geometric configuration, a U-shaped geometric configuration, a V-shaped geometric configuration, or another geometric configuration. The one or more sensors 121 also include a touch sensor 704 to determine whether a user is holding, or predominantly holding, the electronic device 100 by a particular portion of the deformable housing 101. The one or more sensors 121 also include a motion/orientation detector 706 to determine whether the electronic device 100 is moving and its geometric orientation in three-dimensional space, such as whether the electronic device 100 is in a portrait orientation or a landscape orientation. The one or more sensors 121 also comprise one or more proximity sensors 705 that can detect objects approaching, or proximately located with, the deformable housing 101.

It should be noted that the one or more sensors 121 shown in FIG. 7 are not comprehensive, as others will be obvious to those of ordinary skill in the art having the benefit of this disclosure. Additionally, it should be noted that the one or more sensors 121 shown in FIG. 7 could be used alone or in combination. Accordingly, many electronic devices will employ only subsets of the one or more sensors 121 shown in FIG. 7, with the particular subset chosen being defined by device application.

The touch sensor 704 can include a capacitive touch sensor, an infrared touch sensor, resistive touch sensors, or another touch-sensitive technology. Capacitive touch-sensitive devices include a plurality of capacitive sensors, e.g., electrodes, which are disposed along a substrate. Each capacitive sensor is configured, in conjunction with associated control circuitry, e.g., the one or more processors 112, to detect an object in close proximity with—or touching—the surface of the display or the housing of an electronic device by establishing electric field lines between pairs of capacitive sensors and then detecting perturbations of those field lines.

The electric field lines can be established in accordance with a periodic waveform, such as a square wave, sine wave, triangle wave, or other periodic waveform that is emitted by one sensor and detected by another. The capacitive sensors can be formed, for example, by disposing indium tin oxide patterned as electrodes on the substrate. Indium tin oxide is useful for such systems because it is transparent and conductive. Further, it is capable of being deposited in thin layers by way of a printing process. The capacitive sensors may also be deposited on the substrate by electron beam evaporation, physical vapor deposition, or other various sputter deposition techniques.

The motion/orientation detector 706 can include an accelerometer, gyroscopes, or other devices that sense motion or geometric orientation of the electronic device 100 in three-dimensional space. Using an accelerometer as an example, an accelerometer can be included to detect motion of the electronic device. Additionally, the accelerometer can be used to sense some of the gestures of the user, such as one talking with their hands, running, or walking.

The motion/orientation detector 706 can also be used to determine the spatial orientation of an electronic device as well in three-dimensional space by detecting a gravitational direction. In addition to, or instead of, an accelerometer, an electronic compass can be included to detect the spatial orientation of the electronic device relative to the earth's magnetic field. Similarly, one or more gyroscopes can be included to detect rotational motion of the electronic device.

The proximity sensors 705 fall in to one of two camps: active proximity sensors and “passive” proximity sensors. These are referred to as proximity detector components and proximity sensor components. Either the proximity detector components or the proximity sensor components can be generally used for gesture control and other user interface protocols, some examples of which will be described in more detail below.

As used herein, a “proximity sensor component” comprises a signal receiver only that does not include a corresponding transmitter to emit signals for reflection off an object to the signal receiver. A signal receiver only can be used due to the fact that a user's body or other heat generating object external to device, such as a wearable electronic device worn by user, serves as the transmitter. Illustrating by example, in one the proximity sensor components comprise a signal receiver to receive signals from objects external to the housing of an electronic device. In one embodiment, the signal receiver is an infrared signal receiver to receive an infrared emission from an object such as a human being when the human is proximately located with the electronic device. In one or more embodiments, the proximity sensor component is configured to receive infrared wavelengths of about four to about ten micrometers. This wavelength range is advantageous in one or more embodiments in that it corresponds to the wavelength of heat emitted by the body of a human being.

Additionally, detection of wavelengths in this range is possible from farther distances than, for example, would be the detection of reflected signals from the transmitter of a proximity detector component. In one embodiment, the proximity sensor components have a relatively long detection range so as to detect heat emanating from a person's body when that person is within a predefined thermal reception radius. For example, the proximity sensor component may be able to detect a person's body heat from a distance of about ten feet in one or more embodiments. The ten-foot dimension can be extended as a function of designed optics, sensor active area, gain, lensing gain, and so forth.

Proximity sensor components are sometimes referred to as a “passive IR system” due to the fact that the person is the active transmitter. Accordingly, the proximity sensor component requires no transmitter since objects disposed external to the housing deliver emissions that are received by the infrared receiver. As no transmitter is required, each proximity sensor component can operate at a very low power level.

In one embodiment, the signal receiver of each proximity sensor component can operate at various sensitivity levels so as to cause the at least one proximity sensor component to be operable to receive the infrared emissions from different distances. For example, the one or more processors 112 can cause each proximity sensor component to operate at a first “effective” sensitivity so as to receive infrared emissions from a first distance. Similarly, the one or more processors 112 can cause each proximity sensor component to operate at a second sensitivity, which is less than the first sensitivity, so as to receive infrared emissions from a second distance, which is less than the first distance. The sensitivity change can be made by causing the one or more processors 112 to interpret readings from the proximity sensor component differently.

By contrast, proximity detector components include a signal emitter and a corresponding signal receiver. While each proximity detector component can be any one of various types of proximity sensors, such as but not limited to, capacitive, magnetic, inductive, optical/photoelectric, imager, laser, acoustic/sonic, radar-based, Doppler-based, thermal, and radiation-based proximity sensors, in one or more embodiments the proximity detector components comprise infrared transmitters and receivers. The infrared transmitters are configured, in one embodiment, to transmit infrared signals having wavelengths of about 860 nanometers, which is one to two orders of magnitude shorter than the wavelengths received by the proximity sensor components. The proximity detector components can have signal receivers that receive similar wavelengths, i.e., about 860 nanometers.

In one or more embodiments, each proximity detector component can be an infrared proximity sensor set that uses a signal emitter that transmits a beam of infrared light that reflects from a nearby object and is received by a corresponding signal receiver. Proximity detector components can be used, for example, to compute the distance to any nearby object from characteristics associated with the reflected signals. The reflected signals are detected by the corresponding signal receiver, which may be an infrared photodiode used to detect reflected light emitting diode (LED) light, respond to modulated infrared signals, and/or perform triangulation of received infrared signals.

While the one or more sensors 121 shown in FIG. 7 work well to determine whether a user is holding the electronic device 100 by the first end 108, the second end 109, the central portion 128, or somewhere else. An image capture device (104) can be used to perform the same function. The image capture device (104) can be configured to capture an image of an object and determine whether the object matches predetermined criteria. For example, the image capture device (104) can operate as an identification module configured with optical recognition such as include image recognition, character recognition, visual recognition, facial recognition, color recognition, shape recognition and the like. Advantageously, the image capture device (104) can be used as a facial recognition device to determine the identity of one or more persons detected about an electronic device.

For example, in one embodiment when the one or more proximity sensor components detect a person, the image capture device (104) can capture a photograph of that person. The image capture device (104) can then compare the image to a reference file stored in memory (113), to confirm beyond a threshold authenticity probability that the person's face sufficiently matches the reference file. Beneficially, optical recognition allows the one or more processors 112 to execute control operations only when one of the persons detected about the electronic device are sufficiently identified as the owner of the electronic device.

In addition to capturing photographs, the image capture device (104) can function in other ways as well. For example, in some embodiments the image capture device (104) can capture multiple successive pictures to capture more information that can be used to determine when the electronic device 100 is being supported by a surface. Alternatively, the image capture device (104) can capture or video frames, with or without accompanying metadata such as motion vectors.

In one or more embodiments, the thermal mitigation circuit 125 selects which energy storage device of the plurality of energy storage devices 123 will power the one or more processors 112 as a function of a support condition detected by the one or more sensors 121 and, optionally, a geometric configuration of the electronic device 100. Illustrating by example, when the support condition comprises the electronic device 100 being held at the first end 108, the thermal mitigation circuit 125 can select a subset of the plurality of energy storage devices 123 that are separated from the first end 108 by at least one energy storage device excluded from the subset of the plurality of energy storage devices 123, thereby providing a thermal “buffer” between the user and the energy storage devices that are powering the one or more processors 112. Similarly, when the support condition comprises the electronic device 100 being held in a folded position, the thermal mitigation circuit 125 may select a subset of the plurality of energy storage devices 123 comprising a first set of energy storage devices and a second set of energy storage devices separated from the first set of energy storage devices by at least one energy storage device excluded from the subset of the plurality of energy storage devices 123.

When the support condition comprises the electronic device being supported by a surface, the thermal mitigation circuit 125 may select all energy storage devices of the plurality of energy storage devices 123 to power the one or more processors 112 since thermal mitigation between the electronic device 100 and a user touching the electronic device 100 is not at issue. When the support condition comprises the electronic device 100 being held at an end of the electronic device, the thermal mitigation circuit 125 can select a subset of the plurality of energy storage devices 123 situated at another end of the electronic device to power the one or more processors 112.

When the support condition comprises a wrist-worn support condition, in one or more embodiments the thermal mitigation circuit selects all energy storage devices of the plurality of energy storage devices 123 to power the one or more processors 112 so that thermal energy is spread across the entire deformable housing 101. Similarly, when the geometric configuration comprises the electronic device 100 being flat or substantially flat, the thermal mitigation circuit 125 may select all energy storage devices of the plurality of energy storage devices 123 to spread heat across the deformable housing 101 as well. However, when the geometric configuration comprises the electronic device 100 being bent to define a loop, as shown above in FIG. 6, the thermal mitigation circuit 125 may alternatively select a subset of the plurality of energy storage devices 123 to power the one or more processors 112. Illustrating by example, if the electronic device 100 is deformed to define a loop and a user is supporting that loop by a finger or two, the thermal mitigation circuit 125 may select a subset of the plurality of energy storage devices 123 situated at locations other than where the finger (or two) is supporting the loop, and so forth.

In one or more embodiments, the thermal mitigation circuit 125 makes the selection as a function of a support condition of the electronic device 100 and a geometric configuration of the electronic device 100, each detected by the one or more sensors 121 of the electronic device 100.

Illustrating by example, the flex sensor 120 can determine the geometry of the electronic device 100, while the motion/orientation detector 706 determines an orientation of the electronic device 100 in three-dimensional space. Similarly, the proximity sensors 705 and/or touch sensor 704 can determine where the electronic device 100 is being held or supported. Thus, the one or more sensors 121 may determine a support condition that involves the electronic device 100 being held while the geometric configuration comprises the electronic device 100 being in the axially displaced open position.

In one or more embodiments, the support condition comprises the electronic device 100 being held by, or held predominantly by, the first end 108. In one or more embodiments, this results in the thermal mitigation circuit 125 drawing more current from a subset of the plurality of energy storage devices 123 situated near the second end 109. By contrast, when the support condition comprises the electronic device 100 being held by, or held predominantly by, the second end 109, the thermal mitigation circuit 125 will draw more current from a subset of the plurality of energy storage devices 123 situated at the first end 108 as previously described.

When the charger 701 is connected, charging operations can occur in a similar manner. Illustrating by example, in one or more embodiments the thermal mitigation circuit 125, using the charge and discharge control 702,703, determine whether to charge energy storage devices situated at a first end 108, a second end 109, a first end 108 and a second end 109 separated by a central portion 128, and so forth as a function of the support condition of the electronic device 100 detected by the one or more sensors 121 and the geometric configuration of the electronic device 100, also detected by the one or more sensors 121. For instance, when the support condition comprises the electronic device 100 being supported by a surface and the geometric configuration comprises the electronic device 100 being in a partially open position similar to that shown above in FIG. 2, the thermal mitigation circuit 125 may charge all energy storage devices of the plurality of energy storage devices 123.

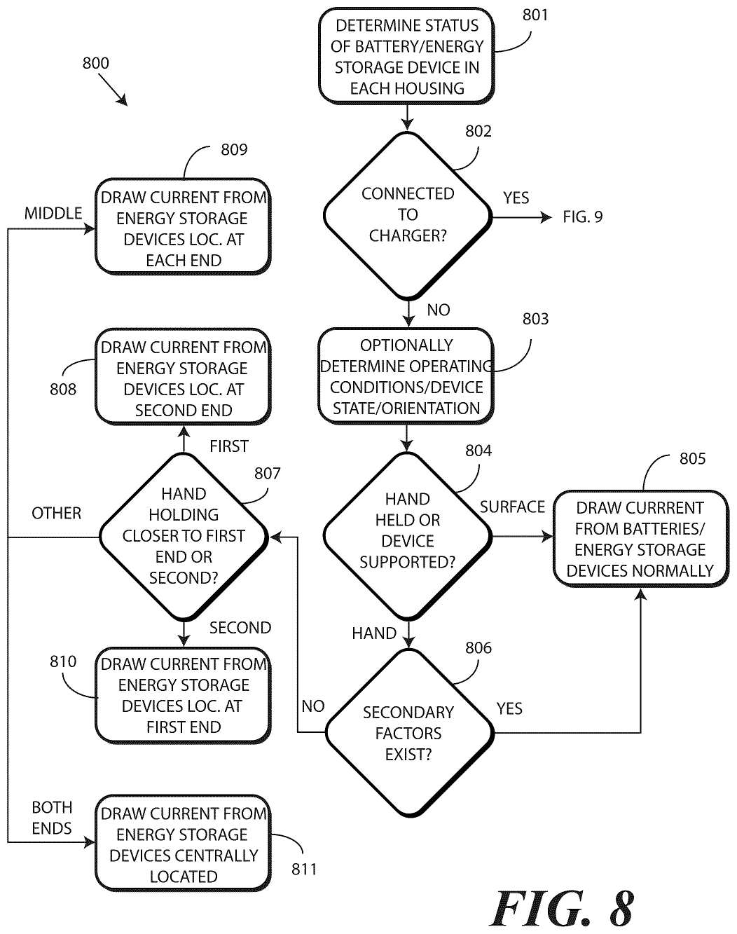

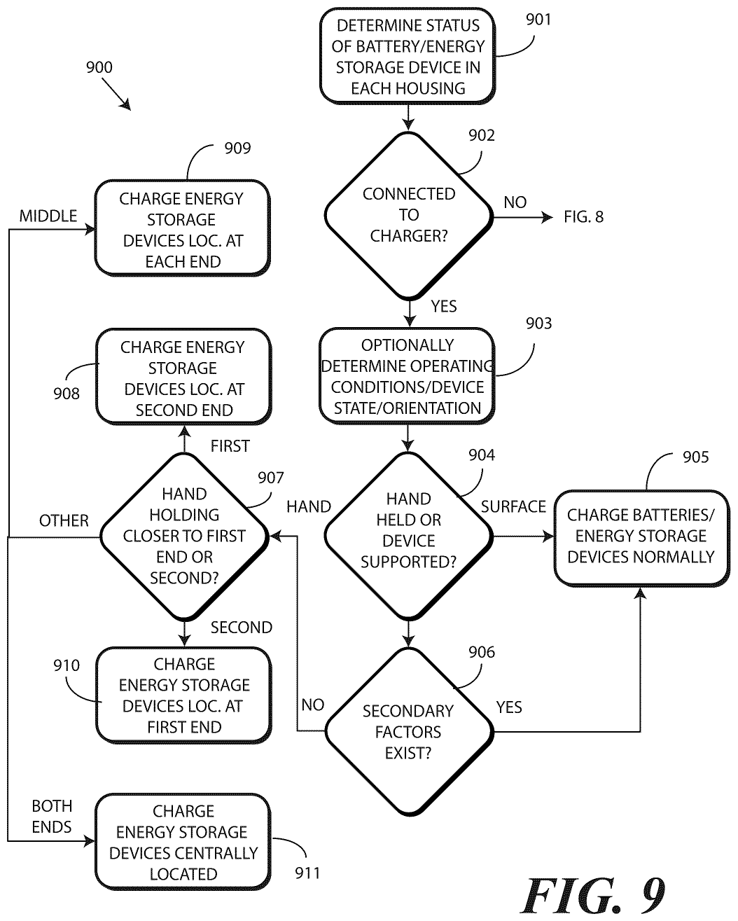

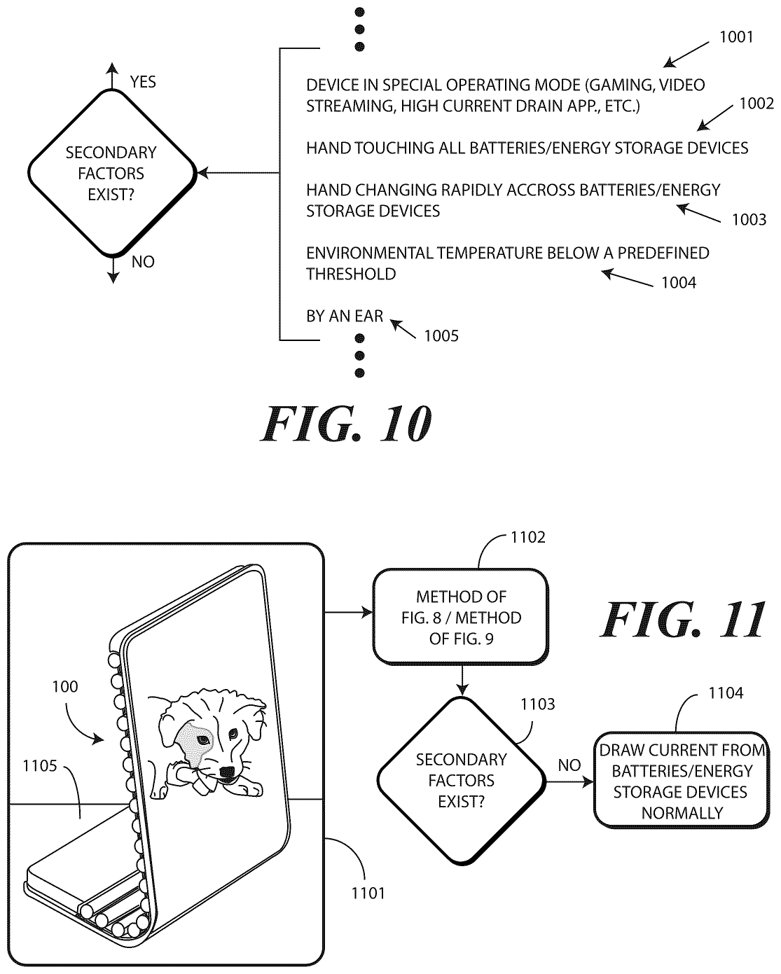

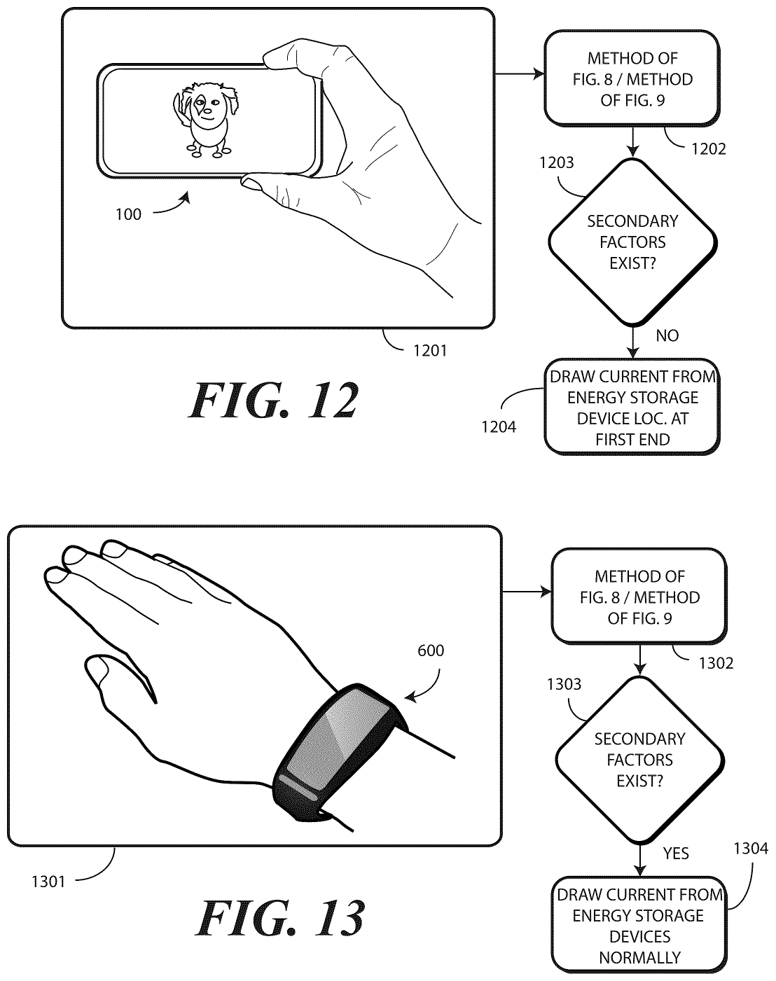

Turning now to FIGS. 8 and 9, illustrated therein are general methods 800,900 for discharging and charging energy storage devices in an electronic device having multiple energy storage devices in accordance with embodiments of the disclosure, respectively. The method 800 of FIG. 8 is directed to determining from which energy storage devices to draw current to power components of an electronic device, while the method 900 of FIG. 9 is directed to determining to which energy storage devices to deliver charging current when a charger, such as that shown above with reference to FIG. 7, is connected to the electronic device. In one or more embodiments, the methods 800,900 are directed to a deformable electronic device comprising a flexible display spanning a first major surface of the deformable electronic device, with a plurality of energy storage devices situated in or along a deformable housing, such that the deformable electronic device can be flat, bent, partially folded, formed into a loop, folded with multiple folds, and so forth.

Beginning with FIG. 8, at step 801 one or more processors or a thermal mitigation circuit of an electronic device determine the amount of energy stored in the energy storage devices of the plurality of energy storage devices. This determination is made in one or more embodiments because if conditions are not sufficiently acceptable, the primary mode of operation where current is drawn from a subset of the plurality of energy storage devices situated at locations of the deformable housing that are not being held cannot occur.

Illustrating by example, when some energy storage devices are charged more than other energy storage devices, and when this difference is within a predefined threshold, drawing current from energy storage devices situated in portions of a deformable device housing not being held works well. However, when the difference exceeds the threshold, to prevent the disparity between energy storage devices from becoming too large, it can be advantageous to at least momentarily (until the disparity falls within the threshold at a minimum) draw current from the energy storage devices situated in the portions of the deformable device housing that are being held.

When charging, while it is generally desirable to charge the energy storage devices in the portions of the deformable device housing not being held. However, if the difference between energy storage levels in the energy storage devices is outside the threshold it can be advantageous to at least momentarily charge the energy storage devices in the portion of the deformable device housing being held, at least until the disparity falls within the threshold.

Decision 802 then determines whether the electronic device is coupled to a charger. Where it is, the method 800 proceeds to FIG. 9. Otherwise, the method 800 proceeds to step 803.

At step 803, one or more sensors of the electronic device optionally determine what conditions the electronic device is experiencing. These conditions can include whether the electronic device is moving or stationary, an orientation of the electronic device in three-dimensional space, e.g., whether it is oriented in a portrait orientation or landscape orientation, how the electronic device is being supported, e.g., by a hand or surface, and the geometric configuration of the electronic device, e.g., whether the electronic device is in the axially displaced open position, a folded position, a partially folded position, a loop, and so forth.

Decision 804 determines whether the electronic device is being supported by a hand or a surface. Techniques for doing this were described above with reference to FIGS. 1 and 7. Other such techniques will be obvious to those of ordinary skill in the art having the benefit of this disclosure.

Where the electronic device is being supported by a hand, the method 800 moves to decision 806. At decision 806, one or more sensors of the electronic device determine whether secondary factors exist. Decision (906) of FIG. 9 is similar to decision 806. Since these decisions are similar, some additional discussion concerning what the secondary factors are and how they can affect the method is warranted.

Turning briefly to FIG. 10, illustrated therein are some additional secondary factors that can be determined at these decision steps of the method. Beginning with special factor 1001, this special factor 1001 occurs when a performance application is operating on one or more processors of the electronic device. Embodiments of the disclosure contemplate that performance applications generally require lots of processing power and therefore lots of current. Accordingly, while it may be desirable to draw current from subset of the plurality of energy storage devices situated at an end of the deformable housing, it may actually be preferable to draw current from all energy storage device of the plurality of energy storage devices despite the fact that the deformable housing is being held at a particular location so that the performance application can run optimally.

Special factor 1002 occurs when a user is touching substantially all, or all, energy storage devices of the plurality of energy storage devices. In such a situation, it can be advantageous to select all energy storage device of the plurality of energy storage devices so as to spread the thermal energy being dissipated across a larger surface area of the deformable housing.

Special factor 1003 occurs when the electronic device is in a landscape orientation while being handheld, with the hand predominantly supporting the electronic device changing very rapidly. Embodiments of the disclosure contemplate that some hysteresis needs to be included so that the system does not toggle rapidly when, for example, a person is rapidly switching the electronic device from the left hand to the right hand and so forth. Accordingly, when special factor 1003 exists, current may be drawn at least momentarily (or delivered to in a charging scenario) from a subset of energy storage devices situated in a portion of the deformable device housing being held so as to prevent the frequent switching.

Special factor 1004 occurs when the ambient temperature around the electronic device becomes too low. Embodiments of the disclosure contemplate that many types of rechargeable batteries, especially lithium-based batteries, do not perform optimally in either extreme heat or extreme cold. Accordingly, in many situations it may be desirable to draw current (or deliver current in a charging scenario) from a subset of energy storage devices situated in the portion of the deformable device housing being held. This can occur instead of, or in addition to drawing/delivering current to/from subsets of the plurality of energy storage devices situated in portions of the deformable housing not being held. The reasons for doing so may include warming the device housing being held to warm the user's hand, warming the energy storage devices themselves so they can perform more optimally, or other reasons.

Special factor 1005 comprises a device housing being adjacent to an ear. As previously described, embodiments of the disclosure contemplate that the ear is frequently more sensitive to temperature than the hand. Accordingly, when a device housing not being held is adjacent to an ear, current may be drawn at least momentarily (or delivered in a charging scenario) to the energy storage devices situated in portions of the deformable device housing being held so as to prevent the ear from becoming too hot.

These examples of secondary factors that might preclude the preferred operation set forth in FIG. 10 are illustrative only. Others will be obvious to those of ordinary skill in the art having the benefit of this disclosure.

Turning now back to FIG. 8, if secondary factors precluding the preferred mode of operation from occurring exists, the method 800 moves to step 805 where current required to power the electronic device is drawn from, or predominantly from, all energy storage devices of the plurality of energy storage devices despite the fact that the user is holding a particular portion of the deformable housing. The same occurs when decision 804 determines the electronic device is being supported by a surface.

At decision 807 the method 800 determines whether the electronic device is being held by, or held predominantly by, a first end, a second end, a central portion, or elsewhere. In one or more embodiments, when the support condition comprises the deformable electronic device being held at a first end, step 808 comprises using a subset of the plurality of energy storage devices separated from the first end by at least one energy storage device excluded from the subset of the plurality of energy storage devices to power the one or more processors. By contrast, when the support condition comprises the deformable electronic device being held at a second end, step 810 comprises using a subset of the plurality of energy storage devices separated from the first end by at least one energy storage device excluded from the subset of the plurality of energy storage devices to power the one or more processors.

When the support condition comprises the deformable electronic device being held at a central portion, step 809 comprises using a subset of the plurality of energy storage devices comprising a first set of energy storage devices and a second set of energy storage devices separated from the first set of energy storage devices by at least one energy storage device excluded from the subset of the plurality of energy storage devices to power the one or more processors. When the support condition comprises the deformable electronic device being held at both ends, step 811 can comprise using a subset of the plurality of energy storage devices situated centrally along the deformable housing and separated by at least one energy storage device at the first end excluded from the subset and at least one other energy storage device situated at the second end and excluded from the subset, and so forth.

Turning now to the method 900 of FIG. 9, the selection of which energy storage devices of the plurality of energy storage devices to charge at a given point in time is illustrated. Beginning with step 901, at this step 901 one or more processors or a thermal mitigation circuit of a deformable electronic device determine the amount of energy stored in the energy storage devices. Scenarios that can occur at this step 901, as well as their implications, were described above with reference to FIG. 8 and are incorporated here by reference.

Decision 902 then determines whether the electronic device is coupled to a charger. Where it is, the method 900 proceeds to FIG. 8. Otherwise, the method 900 proceeds to step 903.

At step 903, one or more sensors of the electronic device optionally determine what conditions the electronic device is experiencing. These conditions can include whether the electronic device is moving or stationary, an orientation of the electronic device in three-dimensional space, e.g., whether it is oriented in a portrait orientation or landscape orientation, how the electronic device is being supported, e.g., by a hand or surface, and the geometric configuration of the electronic device, e.g., whether the electronic device is in the axially displaced open position, the closed position, or positions therebetween.

Decision 904 determines whether the electronic device is being supported by a hand or a surface. Techniques for doing this were described above with reference to FIGS. 1 and 7. Other such techniques will be obvious to those of ordinary skill in the art having the benefit of this disclosure.

Where the electronic device is being supported by a hand, the method 900 moves to decision 906. At decision 906, one or more sensors of the electronic device determine whether secondary factors exist. Secondary factors were described above with reference to FIG. 101 and apply here. These secondary factors include determining conditions such as whether the energy storage level of the energy storage devices is below a predefined threshold. As noted above, it is frequently desirable to deliver current to charge energy storage devices situated at a second end of the deformable housing when a user is holding, or predominantly holding, the first end of the deformable housing. However, if the energy storage devices at the second end are sufficiently charged, this would constitute a secondary consideration that might preclude this preferred method of operation and instead cause current to be delivered to the energy storage devices situated in at the first end of the deformable housing.

If secondary factors precluding the preferred mode of operation from occurring exists, the method 900 moves to step 905 where charging current is delivered to, or predominantly to, all energy storage devices of the plurality of energy storage devices despite the fact that the user is holding a particular portion of the deformable housing. The same occurs when decision 904 determines the electronic device is being supported by a surface.

At decision 907 the method 900 determines whether the electronic device is being held by, or held predominantly by, a first end, a second end, a central portion, or elsewhere. In one or more embodiments, when the support condition comprises the deformable electronic device being held at a first end, step 908 comprises charging a subset of the plurality of energy storage devices separated from the first end by at least one energy storage device excluded from the subset of the plurality of energy storage devices. By contrast, when the support condition comprises the deformable electronic device being held at a second end, step 910 comprises charging a subset of the plurality of energy storage devices separated from the first end by at least one energy storage device excluded from the subset of the plurality of energy storage.

When the support condition comprises the deformable electronic device being held at a central portion, step 909 comprises charging a subset of the plurality of energy storage devices comprising a first set of energy storage devices and a second set of energy storage devices separated from the first set of energy storage devices by at least one energy storage device excluded from the subset of the plurality of energy storage. When the support condition comprises the deformable electronic device being held at both ends, step 911 can comprise charging a subset of the plurality of energy storage devices situated centrally along the deformable housing and separated by at least one energy storage device at the first end excluded from the subset and at least one other energy storage device situated at the second end and excluded from the subset, and so forth.

Now that the general hardware, systems, and methods have been described, attention will be turned to some use cases occurring in accordance with one or more embodiments of the disclosure. The use cases describe below provide illustrations of operations of embodiments of the disclosure both in the presence of, and in the absence of secondary factors. Specifically, FIGS. 11-13 illustrate both use cases in which the preferred mode of operation occurs and other use cases where the preferred mode of operation is precluded by a special factor.

Turning now to FIG. 11, illustrated therein is one such use case. As shown at step 1101, an electronic device 100 configured in accordance with one or more embodiments of the disclosure is being supported by a surface 1105 while in a partially bent configuration (the tent configuration) that is between a flat position and a folded position. After performing the method (800) of FIG. 8 at step 1102 (the method (900) of FIG. 9 could have been performed had the electronic device 100 been coupled to a charger), decision 1103 confirms no secondary factors are occurring. Accordingly, step 1104 draws current to power the one or more processors of the electronic device from all energy storage device of the plurality of energy storage devices.

Turning now to FIG. 12, in this use case the electronic device 100 is in the flat position and is being supported by a hand at a first end of the deformable housing as shown at step 1201. After performing the method (800) of FIG. 8 at step 1202 (the method (900) of FIG. 9 could have been performed had the electronic device 100 been coupled to a charger), decision 1203 confirms that no secondary factors are occurring. Accordingly, at step 1204 current required to power the electronic device 100 is drawn from a subset of plurality of energy storage devices situated at a second end of the deformable housing to prevent the first end that the user is holding from becoming excessively warm. Heat is therefore generated in the second end of the deformable housing, while keeping the first end relatively cool (at least cooler than the second device housing).

Turning now to FIG. 13, illustrated therein is the electronic device 600 of FIG. 6 bent into a loop as shown at step 1301. Moreover, the electronic device 600 is in a wrist-worn configuration. This means that the user's wrist is in contact with all energy storage devices of the plurality of energy storage devices. As described above at special factor (1002) of FIG. 10, this use case therefore includes a secondary factor to be considered.

After performing the method (800) of FIG. 8 at step 1302 (the method (900) of FIG. 9 could have been performed had the electronic device 100 been coupled to a charger), decision 1303 confirms that the secondary factor of a performance application operating on the one or more processors is occurring. Accordingly, at step 1304 current required to power the electronic device 100 is drawn from all energy storage devices of the plurality of energy storage devices to evenly distribute heat around the user's wrist rather than concentrating it in one location.

It should be noted that the use cases illustrated and described with reference to FIGS. 11-13 are illustrative only and represent only a small portion of the myriad of scenarios that can occur when the geometric configurations and orientations of the electronic device, the support conditions, the charge states, and the secondary factors of FIG. 101 are processed using the methods of FIGS. 8 and 9. Accordingly, numerous others will be obvious to those of ordinary skill in the art having the benefit of this disclosure.

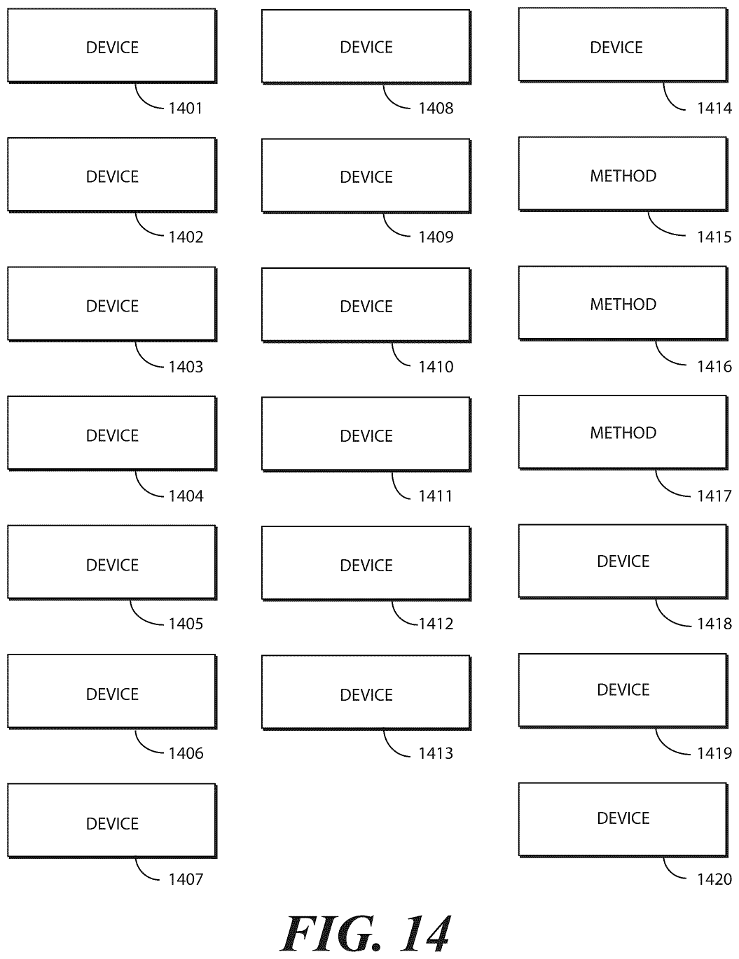

Turning now to FIG. 14, illustrated therein are various embodiments of the disclosure. The embodiments of FIG. 14 are shown as labeled boxes in FIG. 14 due to the fact that the individual components of these embodiments have been illustrated in detail in FIGS. 1-13, which precede FIG. 14. Accordingly, since these items have previously been illustrated and described, their repeated illustration is no longer essential for a proper understanding of these embodiments. Thus, the embodiments are shown as labeled boxes.

At 1401, a deformable electronic device comprises a flexible display supported by a deformable housing comprising a plurality of energy storage devices, one or more processors operable with the flexible display, and one or more sensors operable with the one or more processors. At 1401, a thermal mitigation circuit operable with each energy storage device selects a subset of the plurality of energy storage devices to power the one or more processors as a function of a support condition of the deformable electronic device.

At 1402, when the support condition of 1401 comprises the deformable electronic device being held at a first end of the deformable housing the subset of the plurality of energy storage devices are situated closer to a second end of the deformable housing than the first end of the deformable housing. At 1403, when the support condition of 1402 comprises the deformable electronic device being held at the second end of the deformable housing the subset of the plurality of energy storage devices are situated closer to the first end of the deformable housing than the second end of the deformable housing.

At 1404, when the support condition of 1403 comprises the deformable electronic device being held at a central location of the deformable housing the subset of the plurality of energy storage devices includes a first set of energy storage devices and a second set of energy storage devices separated from the first set of energy storage devices by the central location. At 1405, when the support condition of 1404 comprises the deformable electronic device being supported by a surface the thermal mitigation circuit selects all energy storage devices to power the one or more processors.

At 1406, when the support condition of 1405 comprises the plurality of energy storage devices being held the thermal mitigation circuit selects all energy storage devices to power the one or more processors. At 1407, the deformable housing of 1405 comprises a plurality of linkage members. At 1408, the plurality of energy storage devices of 1407 is situated within the plurality of linkage members on a one-to-one basis with each energy storage device situated in a linkage member.

At 1409, the deformable housing of 1406 comprises a receiver defining a plurality of bays. At 1409, the plurality of energy storage devices is stored in the plurality of bays.

At 1410, when the support condition of 1401 comprises the deformable electronic device being held at a first end of the deformable housing while the deformable electronic device is adjacent to an ear, the subset of the plurality of energy storage devices are situated closer to the first end of the deformable housing than a second end of the deformable housing.

At 1411, the thermal mitigation circuit of 1401 further selects the subset of the plurality of energy storage devices to power the one or more processors as a function of a geometric configuration of the deformable electronic device. At 1412, when the geometric configuration of 1411 comprises the deformable electronic device defining a loop the thermal mitigation circuit selects all energy storage device to power the one or more processors.

At 1413, the deformable electronic device of 1401 further comprises a charger coupled to the deformable electronic device. At 1413, the thermal mitigation circuit further selects another subset of the plurality of energy storage devices to be charged as a function of the support condition of the deformable electronic device.

At 1414, the plurality of energy storage devices of 1410 is situated on a rear side of the deformable electronic device between an electronics component enclosure and an end cap. At 1414, each energy storage device of the plurality of energy storage devices spans a width of the deformable electronic device.

At 1415, a method in a deformable electronic device comprising a flexible display that is deformable around a plurality of energy storage devices comprises determining a subset of the plurality of energy storage devices from which to draw current to power one or more processors of the deformable electronic device as a function of a support condition of the deformable electronic device.

At 1416, the support condition of 1415 comprises the deformable electronic device being held at a first end. At 1416, the subset of the plurality of energy storage devices are separated from the first end by at least one energy storage device excluded from the subset of the plurality of energy storage devices.

At 1417, the support condition of 1415 comprises the deformable electronic device being held at a central portion. At 1417, the subset of the plurality of energy storage devices comprises a first set of energy storage devices and a second set of energy storage devices separated from the first set of energy storage devices by at least one energy storage device excluded from the subset of the plurality of energy storage devices.

At 1418, a deformable electronic device comprises a flexible display spanning a first major surface of the deformable electronic device, a plurality of energy storage devices situated along a second major surface of the deformable electronic device, one or more processors, and one or more sensors. At 1418, the deformable electronic device comprises a thermal mitigation circuit that selects which energy storage devices of the plurality of energy storage devices will power the one or more processors as a function of a support condition detected by the one or more sensors and a geometric configuration of the deformable electronic device.

At 1419, when the support condition of 1418 comprises the deformable electronic device being supported by a surface, the thermal mitigation circuit selects all energy storage devices of the plurality of energy storage devices to power the one or more processors. At 1419, when the support condition of 1418 comprises the deformable electronic device being held at an end of the deformable electronic device, the thermal mitigation circuit selects a subset of the plurality of energy storage devices situated at another end of the deformable electronic device to power the one or more processors. At 1419, when the support condition of 1418 comprises a wrist-worn support condition, the thermal mitigation circuit selects all energy storage devices of the plurality of energy storage devices to power the one or more processors.

At 1420, when the geometric configuration of 1418 comprises the deformable electronic device being flat or substantially flat, the thermal mitigation circuit selects all energy storage devices of the plurality of energy storage devices to power the one or more processors. At 1420, when the geometric configuration of 1418 comprises the deformable electronic device being bent to define a loop, the thermal mitigation circuit selects a subset of the plurality of energy storage devices to power the one or more processors.

In the foregoing specification, specific embodiments of the present disclosure have been described. However, one of ordinary skill in the art appreciates that various modifications and changes can be made without departing from the scope of the present disclosure as set forth in the claims below. Thus, while preferred embodiments of the disclosure have been illustrated and described, it is clear that the disclosure is not so limited. Numerous modifications, changes, variations, substitutions, and equivalents will occur to those skilled in the art without departing from the spirit and scope of the present disclosure as defined by the following claims.

Accordingly, the specification and figures are to be regarded in an illustrative rather than a restrictive sense, and all such modifications are intended to be included within the scope of present disclosure. The benefits, advantages, solutions to problems, and any element(s) that may cause any benefit, advantage, or solution to occur or become more pronounced are not to be construed as a critical, required, or essential features or elements of any or all the claims.

What is claimed is:

1. A deformable electronic device, comprising:
a flexible display supported by a deformable housing comprising a plurality of energy storage devices:
one or more processors operable with the flexible display:
one or more sensors operable with the one or more processors; and
a thermal mitigation circuit operable with each energy storage device, the thermal mitigation circuit selecting a subset of the plurality of energy storage devices to power the one or more processors as a function of a support condition of the deformable electronic device.

2. The deformable electronic device of claim 1, wherein when the support condition comprises the deformable electronic device being held at a first end of the deformable housing the subset of the plurality of energy storage devices are situated closer to a second end of the deformable housing than the first end of the deformable housing.

3. The deformable electronic device of claim 2, wherein when the support condition comprises the deformable electronic device being held at the second end of the deformable housing the subset of the plurality of energy storage devices are situated closer to the first end of the deformable housing than the second end of the deformable housing.

4. The deformable electronic device of claim 3, wherein when the support condition comprises the deformable electronic device being held at a central location of the deformable housing the subset of the plurality of energy storage devices includes a first set of energy storage devices and a second set of energy storage devices separated from the first set of energy storage devices by the central location.

5. The deformable electronic device of claim 4, wherein when the support condition comprises the deformable electronic device being supported by a surface the thermal mitigation circuit selects all energy storage devices to power the one or more processors.

6. The deformable electronic device of claim 5, wherein when the support condition comprises the plurality of energy storage devices being held the thermal mitigation circuit selects all energy storage devices to power the one or more processors.

7. The deformable electronic device of claim 6, the deformable housing comprising a plurality of linkage members.

8. The deformable electronic device of claim 7, wherein the plurality of energy storage devices is situated within the plurality of linkage members on a one-to-one basis with each energy storage device situated in a linkage member.

9. The deformable electronic device of claim 6, the deformable housing comprising a receiver defining a plurality of bays, with the plurality of energy storage devices stored in the plurality of bays.

10. The deformable electronic device of claim 1, wherein when the support condition comprises the deformable electronic device being held at a first end of the deformable housing while the deformable electronic device is adjacent to an ear, the subset of the plurality of energy storage devices are situated closer to the first end of the deformable housing than a second end of the deformable housing.

11. The deformable electronic device of claim 1, the thermal mitigation circuit further selecting the subset of the plurality of energy storage devices to power the one or more processors as a function of a geometric configuration of the deformable electronic device.

12. The deformable electronic device of claim 11, wherein when the geometric configuration comprises the deformable electronic device defining a loop the thermal mitigation circuit selects all energy storage device to power the one or more processors.

13. The deformable electronic device of claim 1, further comprising a charger coupled to the deformable electronic device, the thermal mitigation circuit further selecting another subset of the plurality of energy storage devices to be charged as a function of the support condition of the deformable electronic device.

14. The deformable electronic device of claim 1, wherein the plurality of energy storage devices is situated on a rear side of the deformable electronic device between an electronics component enclosure and an end cap, with each energy storage device of the plurality of energy storage devices spanning a width of the deformable electronic device.

15. A method in a deformable electronic device comprising a flexible display that is deformable around a plurality of energy storage devices, the method comprising determining a subset of the plurality of energy storage devices from which to draw current to power one or more processors of the deformable electronic device as a function of a support condition of the deformable electronic device.

16. The method of claim 15, the support condition comprising the deformable electronic device being held at a first end, wherein the subset of the plurality of energy storage devices are separated from the first end by at least one energy storage device excluded from the subset of the plurality of energy storage devices.

17. The method of claim 15, the support condition comprising the deformable electronic device being held at a central portion, wherein the subset of the plurality of energy storage devices comprises a first set of energy storage devices and a second set of energy storage devices separated from the first set of energy storage devices by at least one energy storage device excluded from the subset of the plurality of energy storage devices.

18. A deformable electronic device, comprising:
a flexible display spanning a first major surface of the deformable electronic device:
a plurality of energy storage devices situated along a second major surface of the deformable electronic device:
one or more processors;
one or more sensors; and
a thermal mitigation circuit;
the thermal mitigation circuit selecting which energy storage devices of the plurality of energy storage devices will power the one or more processors as a function of a support condition detected by the one or more sensors and a geometric configuration of the deformable electronic device.

19. The deformable electronic device of claim 18, wherein:
when the support condition comprises the deformable electronic device being supported by a surface, the thermal mitigation circuit selects all energy storage devices of the plurality of energy storage devices to power the one or more processors;
when the support condition comprises the deformable electronic device being held at an end of the deformable electronic device, the thermal mitigation circuit selects a subset of the plurality of energy storage devices situated at another end of the deformable electronic device to power the one or more processors; and
when the support condition comprises a wrist-worn support condition, the thermal mitigation circuit selects the all energy storage devices of the plurality of energy storage devices to power the one or more processors.

20. The deformable electronic device of claim 18, wherein:
when the geometric configuration comprises the deformable electronic device being flat or substantially flat, the thermal mitigation circuit selects all energy storage devices of the plurality of energy storage devices to power the one or more processors; and
when the geometric configuration comprises the deformable electronic device being bent to define a loop, the thermal mitigation circuit selects a subset of the plurality of energy storage devices to power the one or more processors.
